(19) United States
(12) Patent Application Publication
(10) Pub. No.: US 2026/0293500 A1
(43) Pub. Date: Sep. 24, 2026

(54) DISPLAY DEVICE INCLUDING LENS ALIGNMENT MARK AND ELECTRONIC DEVICE INCLUDING THE DISPLAY DEVICE

(71) Applicant: SAMSUNG DISPLAY CO., LTD., YONGIN-SI (KR)

(72) Inventors: Su Bin JUNG, Yongin-si (KR); Yu Kyung LEE, Yongin-si (KR); Beom Shik KIM, Yongin-si (KR); Jeong Woo PARK, Yongin-si (KR); Su Yeon SIM, Yongin-si (KR)

(21) Appl. No.: 19/365,543

(22) Filed: Oct. 22, 2025

(30) Foreign Application Priority Data
Mar. 19, 2025 (KR) 10-2025-0035102

(51) Int. Cl. H10K 59/80; G02F 1/1333; G02F 1/1335; H10H 29/01; H10H 29/855; H10K 59/12; H10K 59/88

(52) U.S. Cl. CPC H10K 59/879; G02F 1/133374; G02F 1/133526; H10H 29/012; H10H 29/0363; H10H 29/855; H10K 59/1201; H10K 59/88

(57) ABSTRACT

According to embodiments of the present disclosure, a display device includes a display panel including a plurality of pixels, a lens assembly disposed on the display panel at a tilt angle with respect to the display panel, a first base substrate disposed between the display panel and the lens assembly, and a plurality of lens alignment marks disposed on the first base substrate and aligned with the tilt angle.

### CROSS-REFERENCE TO RELATED APPLICATION

This U.S. non-provisional patent application claims priority under 35 U.S.C. §119 to Korean Patent Application No. 10-2025-0035102 filed on Mar. 19, 2025, in the Korean Intellectual Property Office, the entire disclosures of which is incorporated by reference herein

### TECHNICAL FIELD

Embodiments of the present disclosure relate to a display device and, more particularly to, a display device including lens alignment mark and an electronic device including the display device.

### DISCUSSION OF RELATED ART

As the communication technology and the media develop, display devices that display images in various applications and environments including portable electronics, large-area televisions, and vehicle displays are gaining widespread usage. In particular, various types of display devices such as liquid crystal displays (LCDs) and organic light emitting displays (OLEDs) have been widely used.

For example, a stereoscopic image display device configured to divide and display an image onto a spatial region in front of the display device using a lens array has been developed. For example, the stereoscopic image display device includes a binocular parallax-type stereoscopic image display device configured to separate and display a left-eye image and a right-eye image to generate a three-dimensional effect based on a binocular parallax. For example, the stereoscopic image display device includes a light field-type stereoscopic image display device configured to converge light emitted from each lens of a lens array onto a view area corresponding to observation positions of a viewer. Accordingly, research into the light field-type stereoscopic image display device has been actively pursued to implement enhanced three-dimensional (3D) images by increasing the number of view regions and improving angular resolution.

### SUMMARY

According to embodiments of the present disclosure, a display device includes a display panel including a plurality of pixels, a lens assembly disposed on the display panel at a tilt angle with respect to the display panel, a first base substrate disposed between the display panel and the lens assembly, and a plurality of lens alignment marks disposed on the first base substrate and aligned with the tilt angle.

In an embodiment, the display panel may include a display area and a non-display area surrounding the display area, and the plurality of lens alignment marks may include a first lens alignment mark disposed in a display overlap area overlapping the display area, and a second lens alignment mark disposed in a non-display overlap area overlapping the non-display area.

In an embodiment, a width of the first lens alignment mark may be different from a width of the second lens alignment mark.

In an embodiment, the width of the first lens alignment mark may be smaller than the width of the second lens alignment mark.

In an embodiment, the lens assembly may include a plurality of lenses spaced apart from each other by a first interval, and the plurality of lens alignment marks may be spaced apart from each other by the first interval.

In an embodiment, the lens assembly may include a lens boundary portion and a plurality of lenses disposed within the lens boundary portion, and each of the plurality of lens alignment marks may overlap the lens boundary portion.

In an embodiment, the display panel may include a display area and a non-display area surrounding the display area, and a display overlap area overlapping the display area, a vertex formed by a first side and a second side crossing the first side of the display panel, and the plurality of lens alignment marks may include a first lens alignment mark overlapping the vertex.

In an embodiment, the plurality of lens alignment marks may include a second lens alignment mark overlapping the vertex.

In an embodiment, the first lens alignment mark may be disposed in the display overlap area, and the second lens alignment mark may be disposed in a non-display overlap area overlapping the non-display area.

In an embodiment, a width of the first lens alignment mark may be smaller than a width of the second lens alignment mark.

In an embodiment, the display device may further include a second base substrate disposed on and spaced apart from the first base substrate. The plurality of lens alignment marks may include a plurality of lower plate lens alignment marks disposed on the first base substrate, and a plurality of upper plate lens alignment marks disposed on the second base substrate.

In an embodiment, the display panel may include a display area and a non-display area surrounding the display area, and each of the lower plate lens alignment mark and the upper plate lens alignment mark may include a first lens alignment mark disposed in a display overlap area overlapping the display area in a thickness direction of the display panel, and a second lens alignment mark disposed in a non-display overlap area overlapping the non-display area.

In an embodiment, the lens assembly may include a plurality of lenses spaced apart from each other by a first interval, and the plurality of lower plate lens alignment marks may be spaced apart by the first interval, and the plurality of upper plate lens alignment marks may be spaced apart from each other by the first interval.

In an embodiment, the lower plate lens alignment mark may overlap the upper plate lens alignment mark.

In an embodiment, the lens assembly may include a lens boundary portion and a plurality of lenses disposed within the lens boundary portion, and the lower plate lens alignment mark and the upper plate lens alignment mark may overlap the lens boundary portion.

According to embodiments of the present disclosure, an electronic device includes a processor configured to provide an image signal, a display module configured to receive the image signal from the processor and to display an image, and a power module configured to supply power to the display module. The display module includes a display panel including a plurality of pixels, a lens assembly disposed on the display panel at a tilt angle with respect to the display panel, a first base substrate disposed between the display panel and the lens assembly, and a plurality of lens alignment marks disposed on the first base substrate and aligned with the tilt angle.

In an embodiment, the display panel may include a display area and a non-display area surrounding the display area, and the plurality of lens alignment marks may include a first lens alignment mark disposed in a display overlap area overlapping the display area, and a second lens alignment mark disposed in a non-display overlap area overlapping the non-display area.

In an embodiment, the lens assembly may include a plurality of lenses spaced apart from each other by a first interval, and the plurality of lens alignment marks are spaced apart from each other by the first interval.

In an embodiment, the lens assembly may include a lens boundary portion and a plurality of lenses disposed within the lens boundary portion, and the plurality of lens alignment marks may overlap the lens boundary portion.

In an embodiment, the display panel may include a display area and a non-display area surrounding the display area, and a display overlap area overlapping the display area, a vertex formed by a first side and a second side crossing the first side of the display panel, and the plurality of lens alignment marks may include a first lens alignment mark overlapping the vertex.

A display device may be formed by attaching a lens assembly or a lens formed in a titled state at a predetermined angle onto a display panel without separately tilting and attaching an optical member of the display device. According to an embodiment, accurate lamination between the tilted lens formed on a second base substrate and a first base substrate may be performed.

According to an embodiment, by forming a point overlapping a vertex in one of a first side portion and a second side portion, lamination accuracy can be increased and complexity of a design of the display panel can be reduced.

### BRIEF DESCRIPTION OF THE DRAWINGS

The above and other aspects and features of the present disclosure are apparent from the detailed description of the embodiments thereof with reference to the attached drawings, in which:

FIG. 1 is an exploded perspective view illustrating a display device according to an embodiment of the present disclosure;

FIG. 2 is a perspective view of the display device illustrated in FIG. 1;

FIG. 3 is a cross-sectional view illustrating a portion of the display device including emission areas;

FIG. 4 is a cross-sectional view illustrating an always-on light field display;

FIG. 5 is a cross-sectional view illustrating a first type of light field display configured to display a two-dimensional image;

FIG. 6 is a cross-sectional view illustrating the first type of light field display configured to display a three-dimensional image;

FIG. 7 is a cross-sectional view illustrating a second type of light field display configured to display a two-dimensional image;

FIG. 8 is a cross-sectional view illustrating the second type of light field display configured to display a three-dimensional image;

FIGS. 9, 10, 11, 12 and 13, are cross-sectional views illustrating a manufacturing process of a light field display;

FIG. 14 is a plan view illustrating a display panel;

FIG. 15 is a view illustrating a moiré phenomenon occurring due to an lens assembly disposed on the display panel;

FIG. 16 is a view illustrating a tilting arrangement the lens assembly disposed on the display panel to prevent the moiré phenomenon;

FIG. 17 is a cross-sectional view illustrating a display device according to an embodiment of the present disclosure;

FIG. 18 is a cross-sectional view illustrating a display device according to an embodiment of the present disclosure;

FIG. 19 is a plan view illustrating a lower plate lens alignment mark according to an embodiment of the present disclosure;

FIG. 20 is a plan view illustrating a lower plate lens alignment mark according to an embodiment of the present disclosure;

FIG. 21 is a partially enlarged view illustrating portion J1 of FIG. 19;

FIG. 22 is a partially enlarged view illustrating portion J2 of FIG. 19;

FIG. 23 is a partially enlarged view illustrating portion K1 of FIG. 19;

FIG. 24 is a partially enlarged view illustrating portion L of FIG. 19;

FIG. 25 is a plan view illustrating an upper plate lens alignment mark according to an embodiment of the present disclosure;

FIG. 26 is a plan view illustrating an upper plate lens alignment mark according to an embodiment of the present disclosure;

FIG. 27 is a partially enlarged view illustrating portion K2 of FIG. 25;

FIG. 28 is a block diagram of an electronic device according to an embodiment of the present disclosure; and

FIG. 29 is schematic views of electronic devices according to embodiments of the present disclosure.

### DETAILED DESCRIPTION OF THE EMBODIMENTS

Embodiments of the present disclosure are described with reference to the accompanying drawings. However, the inventive concept according to the present disclosure is not necessarily limited to the embodiments disclosed herein, but may be embodied in many different forms, and these embodiments are provided merely to make the disclosure complete and to fully inform one of ordinary skill in the art to which the invention according to the present disclosure belongs.

References to an element or layer as being “on” another element or layer include both cases in which another layer or element is directly on top of or interposed between other elements. The same reference numerals may be used to indicate the same elements disclosure and the drawings. For example, while each drawing may represent one or more particular embodiments of the present disclosure, drawn to scale, such that the relative lengths, thicknesses, and angles can be inferred therefrom, it is to be understood that the present invention is not necessarily limited to the relative lengths, thicknesses, and angles shown. Changes to these values may be made within the spirit and scope of the present disclosure, for example, to allow for manufacturing limitations and the like.

Although the terms “first,” “second,” and the like are used to describe various components, the components are not necessarily limited by these terms. Thus, a first component referred to herein may also be a second component within the technical idea of the present invention.

Each of the features of the various embodiments disclosed herein may be combined or combinable with each other, in part or in whole, and may be technically interlocked and operated in a variety of ways, and each embodiment may be practiced independently of or in conjunction with one another.

Specific embodiments are described below with reference to the accompanying drawings. Configurations that function substantially the same between embodiments are given the same drawing designation and the difference between the embodiments may be described.

Embodiments of the present disclosure provide a display device including an optical member in which a plurality of lenses is formed between a first base substrate and a second base substrate. To ensure accurate lamination of the substrates and alignment of lens boundary portions at a tilted configuration, a plurality of lens alignment marks is disposed on the first base substrate and the second base substrate. The lens alignment marks include lower plate alignment marks disposed adjacent to the first base substrate and upper plate alignment marks disposed adjacent to the second base substrate. The lens alignment marks are distributed across display overlap areas, non-display overlap areas, and cutting areas of the display device. In some cases, auxiliary alignment marks are formed at cutting area to further ensure accurate lamination of the base substrates.

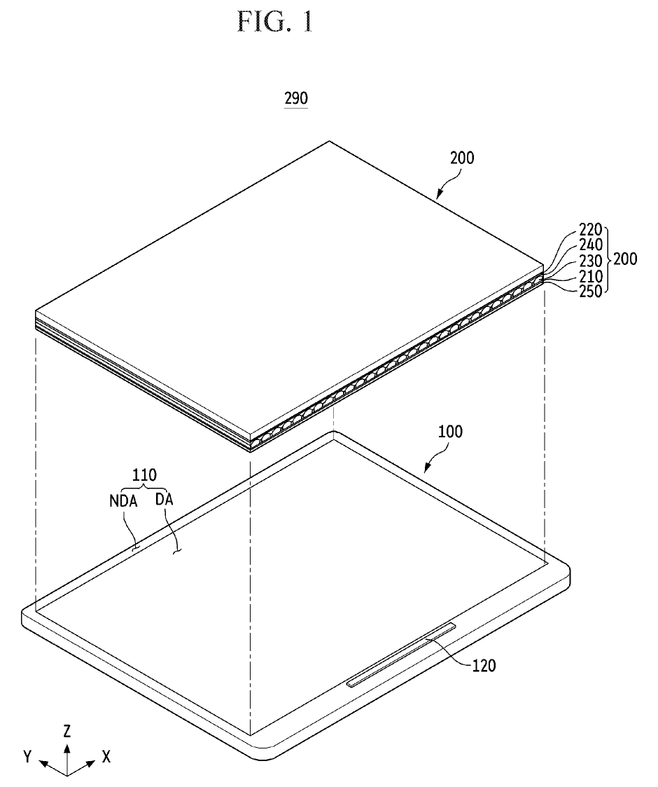

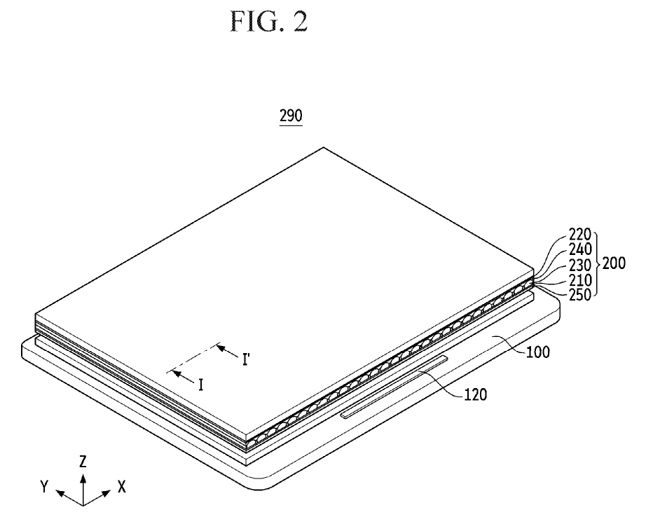

FIG. 1 is an exploded perspective view illustrating a display device according to an embodiment of the present disclosure. FIG. 2 is a perspective view of the display device illustrated in FIG. 1.

A display device 290 may be implemented as a flat panel display device such as a liquid crystal display (LCD), a field emission display (FED), a plasma display panel (PDP), and an organic light emitting display (OLED). In some embodiments, the display device 290 may be implemented as a micro-light emitting diode (micro-LED) display, a quantum-dot light emitting diode (QLED) display, or other emissive and non-emissive display devices.

In one aspect, the display device 290 may be a stereoscopic image display device a three-dimensional (3D) image display device, including a display module 100 and an optical member 200. To display a 3D image, the stereoscopic image display device may separate and display a left-eye image and a right-eye image in a forward viewing direction such that a three-dimensional effect is perceived using based on binocular parallax. Furthermore, the stereoscopic image display device may separate and provide a plurality of viewing angle images toward the forward viewing direction such that different images are perceived at different viewing angles, thereby supporting multi-view image reproduction.

The display device 290 may be a light field display that enables different image information to be viewed by both eyes of the viewer by including the optical member 200 that is disposed on a front surface of the display module 100. The light field display may form a light field and generate a 3D stereoscopic image by using the display module 100 configured to display a two-dimensional (2D) image and the optical member 200 configured to convert the 2D image into a 3D image and output the 3D image. The light field display enables image display light generated from each pixel of the display module 100 to form a light field directed in a specific direction (a specific viewing angle and/or a specific point of view) by a stereoscopic lens, a pinhole, a barrier, or the like, included in the optical member 200. Accordingly, 3D stereoscopic image information corresponding to the specific direction may be provided toward the viewing position of the viewer.

The display module 100 may include a display panel 110 and a display driver 120. In some embodiments, the display module 100 may further include a timing controller, a power storage circuit, or other auxiliary circuits electrically coupled to the display driver 120.

The display panel 110 may include a display area DA and a non-display area NDA. The display area DA may include data lines, scan lines, voltage supply lines, and a plurality of pixels connected to the corresponding data lines and scan lines. For example, the scan lines may extend in a first direction (e.g., an X-axis direction) and may be spaced apart from each other in a second direction (e.g., a Y-axis direction). The data lines and the voltage supply lines may extend in the second direction (e.g., the Y-axis direction) and may be spaced apart from each other in the first direction (e.g., the X-axis direction). In some embodiments, the non-display area NDA may include peripheral circuits such as gate drivers, data drivers, or bonding pads for electrical connection to an external circuit board.

Each pixel (or unit pixel) formed and arranged in the display panel 110 includes a minimum number of sub-pixels capable of emitting white light. For example, each pixel may include three sub-pixels respectively emitting red light, green light, and blue light. Each of the sub-pixels is alternately arranged and electrically connected to at least one scan line, data line, and power supply line. Each of the sub-pixels may include thin film transistors including a driving transistor and at least one switching transistor, a light emitting element, and a capacitor. Each of the pixels may receive a data voltage of the data line when a scan signal is applied from the scan line to each of the pixels, and may emit light by supplying a driving current to the light emitting element according to the data voltage applied to a gate electrode of the driving transistor. In some embodiments, each pixel may further include four sub-pixels each emitting red light, green light, blue light, and white light to improve luminance efficiency.

In an embodiment, the pixels (e.g., the respective unit pixels) of the display panel 110 display a two-dimensional multi-view image based on image data generated by the display driver 120. The multi-view image includes n view images (for example, n is a natural number greater than or equal to 2). For example, the n view images are images generated by capturing an image of a specific object (or content) with n cameras spaced apart from each other using a binocular distance of an ordinary person.

For example, the n view images may include first data by collecting specific content from a first viewing angle, second data by collecting the specific content from a second viewing angle, …, and n-th data by collecting the specific content from an n-th viewing angle. A plurality of data (first data to n-th data) may be digital data. In some embodiments, the plurality of view images may be generated synthetically using computer graphics rendering techniques or machine learning-based interpolation methods, instead of direct capture by physical cameras. In some embodiments, the binocular distance between the cameras may be adjustable or non-uniform to optimize depth perception for particular display or viewing conditions.

The display panel 110 may display the multi-view image in units of n pixels during an image display period. For example, the display panel 110 may display the multi-view image in units of two pixels. For example, two pixels of the display panel 110 may display the multi-view image including two view images. In particular, the display panel 110 may display the multi-view image in units of time-division frame (or sub-frame) periods based on the time-division driving of the display driver 120. For example, the display panel 110 may display the multi-view image in units of two pixels for each time-division frame period. The time-division frame period is a period in which one frame period is divided and driven in units of 1/2 or 1/3 frame periods. In some embodiments, the time-division frame period may be further divided into 1/4 or smaller sub-frame periods to increase the number of supported viewing angles.

The non-display area NDA may surround the display area DA at an edge of the display panel 110. The non-display area NDA may include a scan driver applying scan signals to the scan lines and pads connected to the display driver 120. For example, the display driver 120 may be disposed on one side of the non-display area NDA, and the pads may be disposed at an edge of one side of the non-display area NDA on which the display driver 120 is disposed.

The display driver 120 may output control signals and image data voltages for driving the display panel 110 in units of at least one frame or units of at least one time-division frame (subframe). For example, the display driver 120 may supply image data voltages to the data lines in units of at least one time-division frame (subframe). The display driver 120 may supply a source voltage to the power supply line and supply scan control signals to the scan driver. The image data voltage may include a plurality of data voltages supplied to a plurality of pixels (or sub-pixels) connected to a plurality of data lines. In other embodiments, the display driver 120 may reduce power consumption by using variable refresh rate or low frame-rate driving modes.

The optical member 200 includes a lens assembly 230 (e.g., a refractive index anisotropic lens) formed between first and second base substrates 210 and 220, a polarization control unit 250 formed to overlap the lens assembly 230, and a filler layer 240 filled disposed between the lens assembly 230 and the second base substrate 220. For example, the optical member 200 may include the first base substrate 210, the lens assembly 230, the filler layer 240, and the second base substrate 220 sequentially stacked.

The display driver 120 may be formed as an integrated circuit (IC) and disposed in the non-display area NDA of the display panel 110 in a chip on glass (COG) manner, a chip on plastic (COP) manner, or an ultrasonic bonding manner. As an example, the display driver 120 may be mounted on a circuit board and connected to the pads of the display panel 110.

The optical member 200 may be disposed in a forward viewing direction of the display panel 110 or the display module 100. The optical member 200 may be attached to one surface of the display panel 110 or the display area DA through an adhesive member. For example, an optical member 200 may be laminated with the front surface of the display module 100 using a separate panel lamination device.

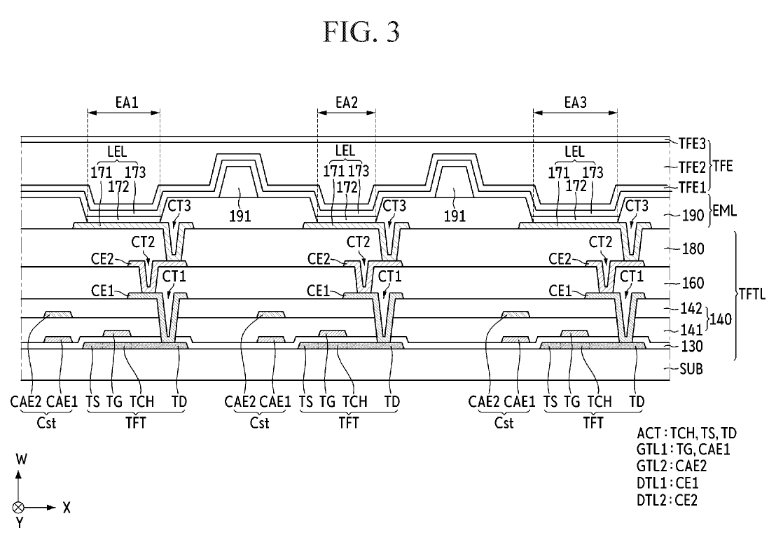

FIG. 3 is a cross-sectional view illustrating a portion of the display device including emission areas.

Referring to FIG. 3, the display panel 110 may include a substrate SUB, a thin film transistor layer TFTL, a light emitting element layer EML, and an encapsulation film TFE. The substrate SUB may be a glass substrate or a flexible polymer substrate configured to support overlying device layers. The thin film transistor layer TFTL may be formed on an upper surface of the substrate SUB, and the light emitting element layer EML may be sequentially stacked above the thin film transistor layer TFTL. The encapsulation film TFE may be disposed to cover the light emitting element layer EML and protect the light emitting element layer EML from oxygen and moisture.

The thin film transistor layer TFTL may include an active layer ACT, a first gate metal layer GTL1, a second gate metal layer GTL2, a first data metal layer DTL1, and a second data metal layer DTL2. In addition, the thin film transistor layer TFTL may include a buffer layer, a gate insulating film 130, a first interlayer insulating film 141, a second interlayer insulating film 142, a first planarization film 160, and a second planarization film 180. The thin film transistor layer TFTL includes a plurality of thin film transistors TFT, and each of the plurality of thin film transistors TFT may include a channel TCH, a gate electrode TG, a first electrode TS, and a second electrode TD.

The active layer ACT may be disposed on the substrate SUB. The active layer ACT may include a silicon semiconductor such as polycrystalline silicon, single crystal silicon, and low-temperature polycrystalline silicon. In some cases, the active layer ACT may include an oxide semiconductor.

For each of the plurality of thin film transistors TFT, the active layer ACT may include the channel TCH, the first electrode TS, and the second electrode TD. The channel TCH may be a region overlapping the gate electrode TG of the thin film transistor TFT in a fourth direction (e.g., a W-axis direction), which corresponds to a thickness direction of the substrate SUB. The first electrode TS may be disposed on one side of the channel TCH, and the second electrode TD may be disposed on the other side of the channel TCH. The first electrode TS and the second electrode TD are positioned such that the first electrode TS and the second electrode TD do not overlap the gate electrode TG in the fourth direction (e.g., the W-axis direction). The first electrode TS and the second electrode TD are formed as doped regions of the semiconductor layer, where the doping ions impart conductivity to the silicon or oxide semiconductor material.

The gate insulating film 130 may be disposed on the active layer ACT. The gate insulating film 130 may be formed as an inorganic film such as a silicon nitride layer, a silicon oxynitride layer, a silicon oxide layer, a titanium oxide layer, or an aluminum oxide layer. In some embodiments, the gate insulating film 130 may include a multi-layer stack of two or more inorganic films. In some embodiments, the gate insulating film 130 may further include an organic-inorganic dielectric layer.

The first gate metal layer GTL1 may be disposed on the gate insulating film 130. The first gate metal layer GTL1 may include the gate electrode TG for each of the plurality of thin film transistors TFT and a first capacitor electrode CAE1. The first gate metal layer GTL1 may be formed as a single layer or multiple layers including at least one of molybdenum (Mo), aluminum (Al), chromium (Cr), gold (Au), titanium (Ti), nickel (Ni), neodymium (Nd), and copper (Cu), or alloys thereof.

The first interlayer insulating film 141 may be disposed on the first gate metal layer GTL1. The first interlayer insulating film 141 may be formed as an inorganic film such as a silicon nitride layer, a silicon oxynitride layer, a silicon oxide layer, a titanium oxide layer, or an aluminum oxide layer. In some embodiments, the first interlayer insulating film 141 may be a multi-layer dielectric stack including alternating nitride and oxide films. In some cases, the first interlayer insulating film 141 may serve as a planarization layer.

The second gate metal layer GTL2 may be disposed on the first interlayer insulating film 141. The second gate metal layer GTL2 may include a second capacitor electrode CAE2. The second capacitor electrode CAE2 may overlap the first capacitor electrode CAE1 in the fourth direction (e.g., the W-axis direction). A capacitor Cst may include the first capacitor electrode CAE1 and the second capacitor electrode CAE2. The second gate metal layer GTL2 may be formed as a single layer or multiple layers including at least one of molybdenum (Mo), aluminum (Al), chromium (Cr), gold (Au), titanium (Ti), nickel (Ni), neodymium (Nd), and copper (Cu), or alloys thereof.

The second interlayer insulating film 142 may be disposed on the second gate metal layer GTL2. The second interlayer insulating film 142 may be formed as an inorganic film such as a silicon nitride layer, a silicon oxynitride layer, a silicon oxide layer, a titanium oxide layer, or an aluminum oxide layer. In some embodiments, the second interlayer insulating film 142 may be a multilayer stack including alternating nitride and oxide layers to enhance barrier characteristics and reduce leakage current.

The first data metal layer DTL1 including a first connection electrode CE1 may be disposed on the second interlayer insulating film 142. The first connection electrode CE1 may be connected to the first electrode TS or the second electrode TD of the thin film transistor TFT through a first contact hole CT1 penetrating through the gate insulating film 130, the first interlayer insulating film 141, and the second interlayer insulating film 142. The first data metal layer DTL1 may be formed as a single layer or multiple layers including at least one of molybdenum (Mo), aluminum (Al), chromium (Cr), gold (Au), titanium (Ti), nickel (Ni), neodymium (Nd), and copper (Cu), or alloys thereof.

The first planarization film 160 may be disposed on the first data metal layer DTL1. For example, the first planarization film 160 may serve as a planarization layer so that an upper surface of the first planarization film 160 diposed on the active layer ACT, the first gate metal layer GTL1, the second gate metal layer GTL2, and the first data metal layer DTL1 is substantially flat. The first planarization film 160 may be formed as an organic film made of an acrylic resin, an epoxy resin, a phenolic resin, a polyamide resin, a polyimide resin, or other resins. In some embodiments, the first planarization film 160 may further include a filler material to improve surface leveling.

The second data metal layer DTL2 may be disposed on the first planarization film 160. The second data metal layer DTL2 may include a second connection electrode CE2. The second connection electrode CE2 may be connected to the first connection electrode CE1 through a second contact hole CT2 penetrating through the first planarization film 160. The second data metal layer DTL2 may be formed as a single layer or multiple layers including at least one of molybdenum (Mo), aluminum (Al), chromium (Cr), gold (Au), titanium (Ti), nickel (Ni), neodymium (Nd), and copper (Cu), or alloys thereof. In some embodiments, the second data metal layer DTL2 may further include a barrier metal layer such as titanium nitride (TiN) or tantalum nitride (TaN).

The second planarization film 180 may be disposed on the second data metal layer DTL2. The second planarization film 180 may be formed as an organic film made of an acrylic resin, an epoxy resin, a phenolic resin, a polyamide resin, a polyimide resin, or other resins. In some cases, for example, the second planarization film 180 may cover the second data metal layer DTL2 and the first planarization film 160.

The light emitting element layer EML may be disposed on the second planarization film 180. The light emitting element layer EML may include a plurality of light emitting elements LEL and a pixel defining film 190. Each of the plurality of light emitting elements LEL may be an organic light emitting diode element including a pixel electrode 171, a light emitting layer 172, and a common electrode 173, but an embodiment of the present disclosure is not necessarily limited thereto. For example, the light emitting element layer EML may include inorganic micro-light emitting diode (micro-LED) elements or quantum-dot structures

The pixel electrode 171 may be disposed on the second planarization film 180. The pixel electrode 171 may be connected to the second connection electrode CE2 through a third connection hole CT3 penetrating through the second planarization film 180.

In a top emission structure (or an upper portion of the light emitting layer 172) in which light is emitted toward the common electrode 173 through the light emitting layer 172, the pixel electrode 171 may include a metal material having high reflectivity, such as a stacked structure (Ti/Al/Ti) of aluminum and titanium, a stacked structure (ITO/Al/ITO) of aluminum and indium tin oxide (ITO), an APC alloy, and a stacked structure (ITO/APC/ITO) of an APC alloy and ITO. The APC alloy is an alloy including silver (Ag), palladium (Pd), and copper (Cu).

The pixel defining film 190 may cover an edge of each of the pixel electrodes 171 on the second planarization film 180 in order to define a plurality of emission areas EA1, EA2, and EA3. The pixel defining film 190 may be formed as an organic film made of an acrylic resin, an epoxy resin, a phenolic resin, a polyamide resin, a polyimide resin, or other resins. In some embodiments, the pixel defining film 190 may include black resin materials to reduce optical crosstalk between adjacent sub-pixels. By surrounding the edges of the pixel electrodes 171 and defining the emission areas EA1, EA2, and EA3, the pixel defining film 190 may reduce electrical and optical crosstalk between adjacent sub-pixels, enhance emission uniformity, and enable higher resolution in stereoscopic multi-view image reproduction.

Each of the plurality of emission areas EA1, EA2, and EA3 refers to an area where the pixel electrode 171, the light emitting layer 172, and the common electrode 173 are sequentially stacked. Additionally, each of the plurality of emission areas EA1, EA2, and EA3 may include holes from the pixel electrode 171 and electrons from the common electrode 173 in the light emitting layer 172 that emit light. In some embodiments, the emission areas EA1, EA2, and EA3 may correspond to red, green, and blue sub-pixels, respectively. In other embodiments, one or more of the emission areas may correspond to a white or yellow sub-pixel.

The light emitting layer 172 may be disposed on the pixel electrode 171. The light emitting layer 172 may include an organic material configured to emit light having a selected color. For example, the light emitting layer 172 may include a hole transporting layer, an organic material layer, and an electron transporting layer.

The common electrode 173 may be disposed on the light emitting layer 172. The common electrode 173 may cover the light emitting layer 172. The common electrode 173 may be a common layer formed in common in the plurality of emission areas EA1, EA2, and EA3. A capping layer may be formed on the common electrode 173. In some embodiments, the capping layer may be a transparent inorganic oxide layer or an organic protective layer.

An upper region or upper surface of the common electrode 173 may include a transparent conductive material (TCO) such as ITO or indium zinc oxide (IZO) capable of transmitting light or a semi-transmissive conductive material such as magnesium (Mg), silver (Ag), or an alloy of magnesium (Mg) and silver (Ag). When the common electrode 173 includes the semi-transmissive conductive material, light emission efficiency may be increased by an optical micro cavity. In some embodiments, the common electrode 173 may further include multilayer dielectric structures.

A spacer 191 may be disposed on the pixel defining film 190. The spacer 191 may serve to support a mask during a process of manufacturing the light emitting layer 172. The spacer 191 may be formed as an organic film made of an acrylic resin, an epoxy resin, a phenolic resin, a polyamide resin, a polyimide resin, or other resins. In some embodiments, the spacer 191 may be formed as an inorganic film.

The encapsulation film TFE may be disposed on the common electrode 173. The encapsulation film TFE may include at least one inorganic film, which prevents oxygen or moisture from permeating into the light emitting element layer EML. In addition, the encapsulation film TFE may include at least one organic film that protects the light emitting element layer EML from foreign substances such as dust. For example, the encapsulation film TFE may include a first encapsulation inorganic film TFE1, an encapsulation organic film TFE2, and a second encapsulation inorganic film TFE3. In some embodiments, the encapsulation film TFE may be implemented as a multi-layer stacked structure having alternating inorganic and organic layers.

The first encapsulation inorganic film TFE1 may be disposed on the common electrode 173, the encapsulation organic film TFE2 may be disposed on the first encapsulation inorganic film TFE1, and the second encapsulation inorganic film TFE3 may be disposed on the encapsulation organic film TFE2. Each of the first encapsulation inorganic film TFE1 and the second encapsulation inorganic film TFE3 may be formed as multiple films in which one or more inorganic films of a silicon nitride layer, a silicon oxynitride layer, a silicon oxide layer, a titanium oxide layer, and an aluminum oxide layer are alternately stacked. The encapsulation organic film TFE2 may be an organic film made of an acrylic resin, an epoxy resin, a phenolic resin, a polyamide resin, a polyimide resin, or other resins.

As illustrated in FIG. 3, for example, the width of a third emission area EA3 is greater than the width of a first emission area EA1, and the width of the first emission area EA1 is greater than the width a second emission area EA2. For example, the first emission area EA1 may be a red emission area, the second emission area EA2 may be a green emission area, and the third emission area EA3 may be a blue emission area. However, an embodiment of the present disclosure is not necessarily limited to relative sizes of the emission areas. For example, the relative sizes of the emission areas EA1, EA2, and EA3 may be varied based on a target color balance or application requirements.

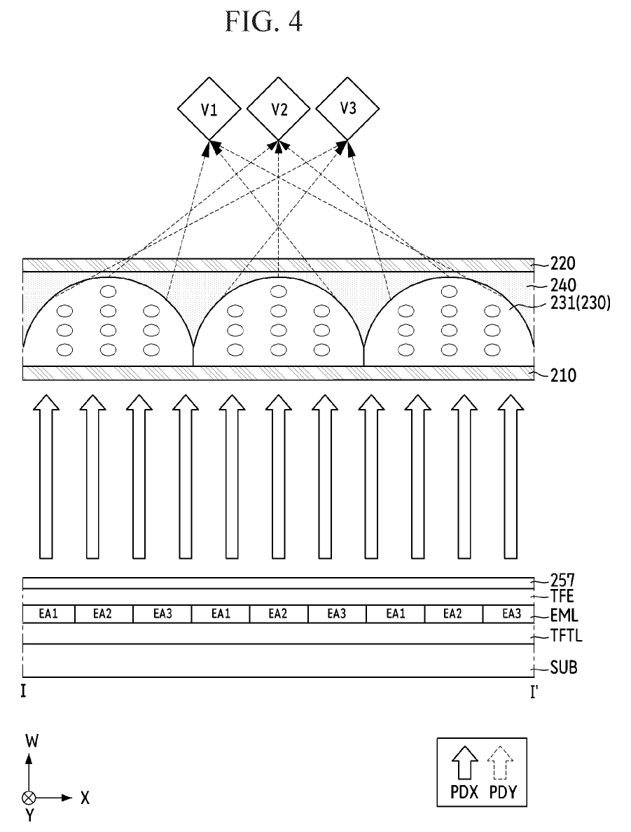

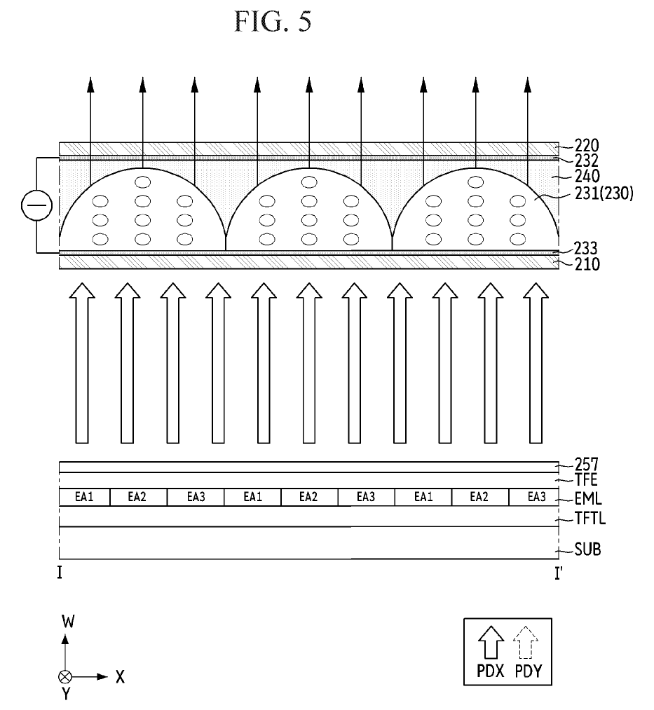

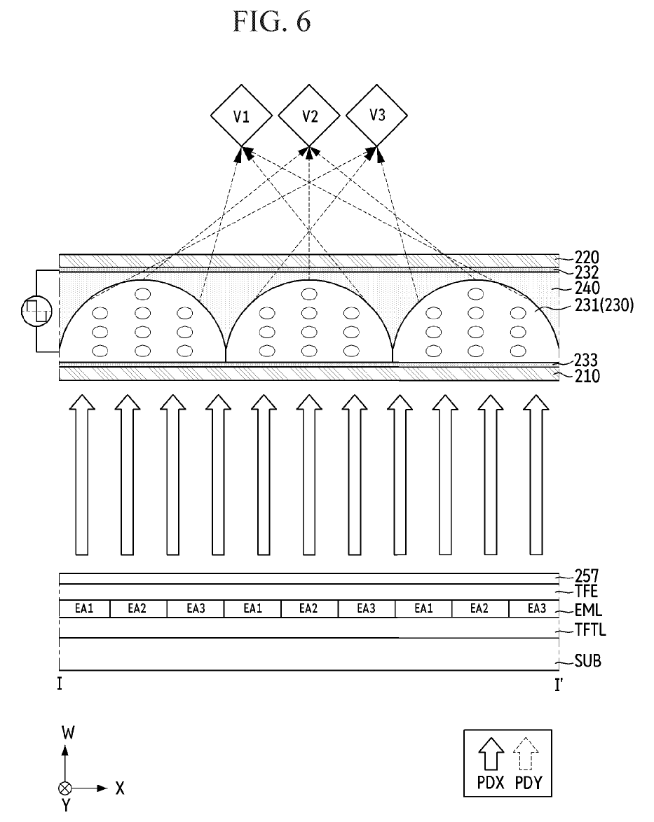

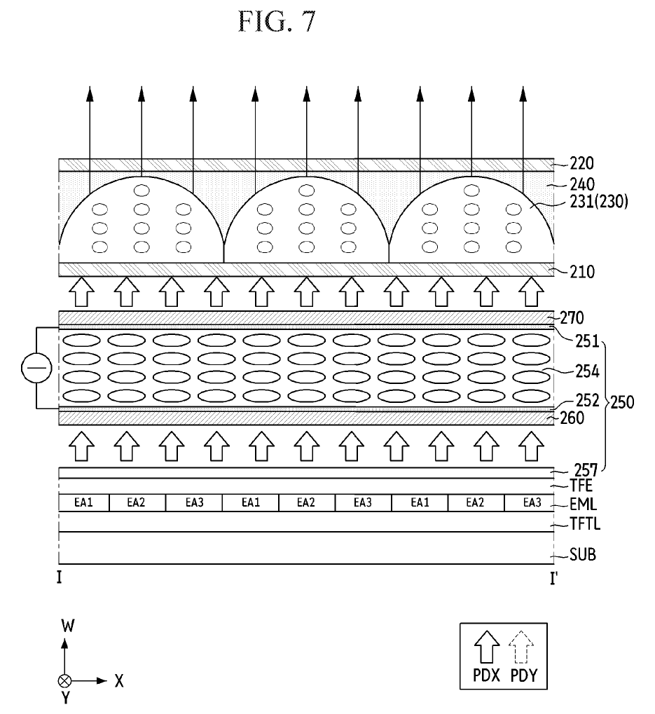

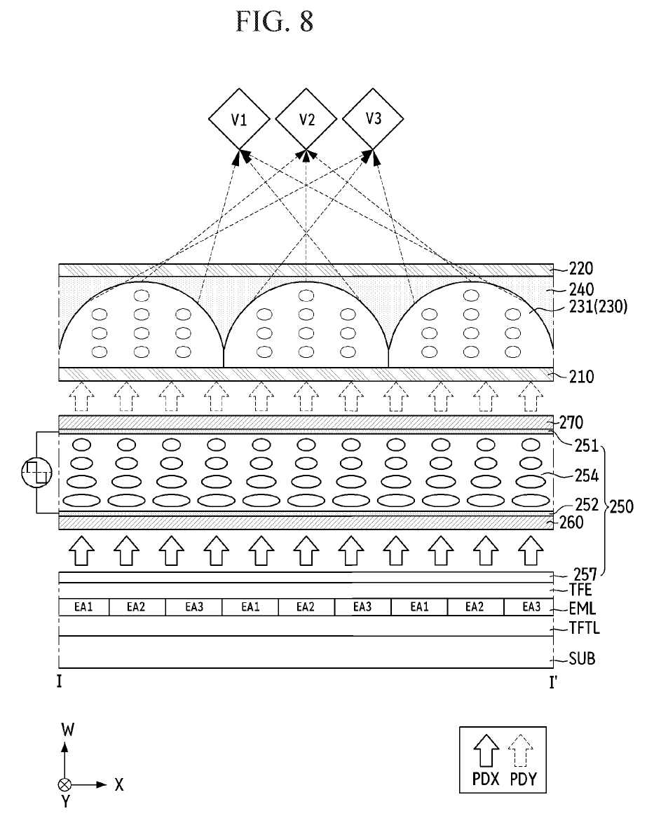

FIG. 4 is a cross-sectional view illustrating an always-on light field display. FIG. 5 is a cross-sectional view illustrating a first type of light field display configured to display a two-dimensional image. FIG. 6 is a cross-sectional view illustrating the first type of light field display configured to display a three-dimensional image. FIG. 7 is a cross-sectional view illustrating a second type of light field display configured to display a two-dimensional image. FIG. 8 is a cross-sectional view illustrating the second type of light field display configured to display a three-dimensional image.

The light field display may allow different image information to be viewed by both eyes of the viewer by including the optical member disposed on the front surface of the display module, as described above. The light field display may be configured to display a two-dimensional image or a three-dimensional image. In some embodiments, the light field display may dynamically switch between the two-dimensional image mode and the three-dimensional image mode based on control signals supplied to the optical member.

A specific content may include not only real-world content, such as texts, pictures, things, and objects, but also digital or virtual content generated computationally and does not exist in the real world. First data may be derived by collecting the specific content from a first viewing angle. Second data may be derived by collecting the specific content from a second viewing angle. Furthermore, n-th data may be derived when the specific content is collected from an n-th viewing angle. In some embodiments, the multi-angle content may be generated using a plurality of physical cameras arranged with predetermined spacing, or using computer graphics rendering or machine learning-based view synthesis.

According to an embodiment, the display device may include a display panel in which a plurality of light emitting elements are disposed and an optical member disposed on the display panel. Light emitted from each light emitting element disposed in the display panel may be refracted while passing through the optical member based on whether a 3D image is to be displayed. For example, when the 3D image is to be displayed, the light emitted from any light emitting element may be refracted in the optical member. For example, when a 2D image is to be displayed, the light emitted from any light emitting element might not be refracted in the optical member.

However, even when the 2D image is to be displayed, the light emitted from the corresponding light emitting element may be refracted, and for example, a resolution deterioration problem of the display device may occur.

A viewing angle may be assigned to each of the plurality of light emitting elements by adjusting refraction directions of light emitted from the plurality of light emitting elements. This may be referred to as viewing angle mapping. In order to adjust the directions of the light emitted from the light emitting elements, a pitch, a tilt angle, and other parameters of lenses (e.g., slanted lenses) included in the optical member may be adjusted.

A specific viewing angle may be mapped to each of the plurality of light emitting elements, and light emitted from the light emitting element to which the specific viewing angle is mapped may travel in a direction of the assigned viewing angle. For example, light emitted from a light emitting element to which the first viewing angle is mapped may travel in a direction of the first viewing angle where a first view area is disposed, and light emitted from a light emitting element to which the second viewing angle is mapped may travel in a direction of the second viewing angle where a second view area is disposed. In some embodiments, a plurality of additional viewing angles may be mapped to generate multiple view areas.

The first data derived by collecting the specific content from the first viewing angle may be input to the light emitting element to which the first viewing angle is mapped. similarly, the second data may be input to the light emitting element to which the second viewing angle is mapped. In some embodiments, data corresponding to a plurality of view angles may be simultaneously or sequentially provided to the corresponding light emitting elements.

The first viewing angle may be disposed on one side (e.g., the left eye side) from the center of both eyes of a viewer. The second viewing angle may be disposed on the other side (e.g., the right eye side) from the center of both eyes of the viewer.

When different images are perceived by the viewer’s left and right eyes regardless of which viewing angle is mapped, the viewer may feel that a three-dimensional image is displayed from the display device. When the same image is perceived by the viewer’s left and right eyes, the viewer may feel that a two-dimensional image is displayed from the display device. For example, when the same image is perceived by the viewer’s left and right eyes, light emitted from the display panel might not be refracted. However, as described above, even though the light emitted from the display panel is refracted, the same image may be perceived by the viewer’s left and right eyes, and for example, a resolution deterioration problem of the display device may occur. Thus, controlling the refraction of light emitted from the display device may enhance the resolution of the images.

Accordingly, the viewer may perceive a three-dimensional image when the first data is input to the light emitting element corresponding to the first viewing angle and the second data is input to the light emitting element corresponding to the second viewing angle.

Alternatively, the viewer may perceive a two-dimensional image when the first data is input to both the light emitting element corresponding to the first viewing angle and the light emitting element corresponding to the second viewing angle. The light emitted from the light emitting element corresponding to the first viewing angle may be refracted even when the two-dimensional image is displayed, and the light emitted from the light emitting element corresponding to the second viewing angle may be refracted.

Alternatively, the two-dimensional image may be displayed when the light emitted from the light emitting element might not be refracted in the optical member. For example, any light emitted from the light emitting element is not refracted regardless of the viewing angle is mapped to the light emitting element, and thus, the viewer may perceive the two-dimensional image. A resolution of the two-dimensional image displayed as described above may be relatively greater than a resolution of the two-dimensional image displayed when the light is refracted and the same image can be perceived by the viewer’s both eyes.

For example, the two-dimensional image may be displayed when the light emitted from the light emitting element is not refracted in the optical member or when the same data is input to light emitting elements even though the light emitted from the light emitting element is refracted in the optical member. In addition, resolutions of the two-dimensional images in each case may be different from each other.

The light field display may include a switchable display device configured to determine whether to display the two-dimensional image or the three-dimensional image by adjusting whether the light emitted from the display panel is refracted. The light field display may include an always-on light field display in which the light emitted from the display panel is always refracted. When the always-on light field display refract the light emitted from the display, the two-dimensional image may be displayed when the same data is input to the light emitting elements regardless of the viewing angle. When the two-dimensional image is displayed in the always-on light field display, a resolution deterioration problem may occur.

The switchable display device may determine whether to display the two-dimensional image or the three-dimensional image by adjusting a linear polarization direction of the light emitted from the display panel and utilizing refractive index anisotropy of lenses included in the lens assembly.

For example, the light emitted from the display panel may pass through a polarizing member disposed above the display panel and pass along a first linear polarization direction.

In an embodiment, a minor axis direction of the lens included in the lens assembly may coincide with the first linear polarization direction. A major axis direction of the lens may coincide with a second linear polarization direction.

The lens assembly may further include a filler layer disposed on a plurality of lenses. The plurality of lenses may have birefringence characteristics. For example, a refractive index of the lens in the minor axis direction may be the same as a refractive index of the filler layer, and a refractive index of the lens in the major axis direction may be greater than the refractive index of the filler layer. However, embodiments of the present disclosure are not necessarily limited thereto.

For example, when a voltage is not applied to the lens, the minor axis direction of the lens may be parallel to the path in the first linear polarization direction. When the light having the path in the first linear polarization direction and emitted from the display panel passes through the lens, the light may experience the refractive index of the lens in the minor axis direction coinciding with the first linear polarization direction. Since the refractive index of the lens in the minor axis direction is the same as the refractive index of the filler layer, the light passing through the lens may travel straight without being refracted at an interface between the lens and the filler layer. For example, since the light is not refracted, light perceived by both eyes of the viewer may be the straight traveling light, and the viewer may perceive a two-dimensional image. Such a mechanism may be applied to the first type of light field display in which the two-dimensional image is displayed(see FIG. 5).

For example, when a voltage is applied to the lens, the major axis direction of the lens may be parallel to the path in the first linear polarization direction. When the light having the path in the first linear polarization direction and emitted from the display panel passes through the lens, the light may experience the refractive index of the lens in the major axis direction coinciding with the first linear polarization direction. Since the refractive index of the lens in the major axis direction is greater than the refractive index of the filler layer, the light passing through the lens may be refracted at the interface between the lens and the filler layer. For example, since the light is refracted, light perceived by both eyes of the viewer may be the refracted light, and the viewer may perceive a three-dimensional image. Such a mechanism may be applied to the first type of light field display in which the three-dimensional image is displayed (see FIG. 6). Accordingly, this operating mode enables stereoscopic generation by directing different image information toward different viewing angles towards the viewer.

In the second type of light field display, a voltage might not be applied to the lens, and the minor axis direction and the major axis direction of the lens may be fixed and parallel to the first linear polarization direction and the second linear polarization direction, respectively (see FIGS. 7 and 8). Instead, the light having the path in the first linear polarization direction and emitted from the display panel may pass through a separate driving liquid crystal disposed between driving electrodes. Light passing through the driving liquid crystal, where a voltage is not applied, may pass through the driving liquid crystal while being maintained at the path in the first linear polarization direction (see FIG. 7). Light passing through the driving liquid crystal, where a voltage is applied, may pass through the driving liquid crystal while being switched from the path in the first linear polarization direction to a path in the second linear polarization direction (see FIG. 8).

Since the minor axis direction and the major axis direction of the lens are parallel to the first linear polarization direction and the second linear polarization direction, respectively, when the light passing through the driving liquid crystal has the path in the first linear polarization direction, the light may experience the refractive index of the lens in the minor axis direction. When the light passing through the driving liquid crystal has the path in the second linear polarization direction, the light may experience the refractive index of the lens in the major axis direction. Since the refractive index of the lens in the minor axis direction is the same as the refractive index of the filler layer and the refractive index of the lens in the major axis direction is greater than the refractive index of the filler layer, the refraction of the light passing through the driving liquid crystal can be determined at the interface between the lens and the filler layer based on the linear polarization direction of the light passing through the driving liquid crystal. Accordingly, the second type of light field display enables switching between two-dimensional and three-dimensional modes by controlling polarization direction within the driving liquid crystal.

As described above, the switchable light field display may include the first type of light field display (see FIGS. 5 and 6) and the second type of light field display (see FIGS. 7 and 8). These two types of light field displays provide alternative mechanisms for switching between two-dimensional and three-dimensional display modes.

In the first type of light field display, as described above, the linear polarization direction of the light passing through the display panel is not changed. Instead, the first type of light field display may directly change the major axis direction and the minor axis direction of the lens having birefringence characteristics. Any changed axis direction coincides with the linear polarization direction of the light passing through the display panel, and the light may pass through the interface while experiencing the refractive index of the lens in the corresponding changed axis direction. Accordingly, the first type enables polarization-independent switching by electrically controlling the orientation of the birefringent lens.

In the second type of light field display, the light passing through the display panel may have the linear polarization direction changed while passing through the driving liquid crystal. In contrast, the second type of light field display might not directly change the major axis direction and the minor axis direction of the lens having the birefringence characteristics. Accordingly, the linear polarization direction of the light passing through the driving liquid crystal coincides with a fixed axis direction of the lens, and the light may pass through the interface while experiencing a corresponding refractive index of the lens in the fixed axis direction.

Referring to FIGS. 7 and 8, in the second type of light field display, the display panel may include a substrate SUB, a thin film transistor layer TFTL, a light emitting element layer EML, and an encapsulation film TFE. These structural elements correspond to the elements described with respect to FIG. 3.

The substrate SUB may have rigidity to support an element formed on the substrate SUB. For example, the substrate SUB may be a glass substrate or a plastic substrate such as a polyethylene terephthalate (PET) substrate. In some embodiments, the substrate SUB may be a flexible polymer substrate.

The thin film transistor layer TFTL may be disposed on the substrate SUB. The thin film transistor layer TFTL may adjust brightness of the display device 290. The thin film transistor layer TFTL may include transistors. In some cases, the thin film transistor layer TFTL may include capacitor elements configured to stabilize voltage applied to the light emitting elements.

The light emitting element layer EML may be disposed on the thin film transistor layer TFTL. The light emitting element layer EML may include first, second, and third emission areas EA1, EA2, and EA3. The first, second, and third emission areas EA1, EA2, and EA3 may be alternately disposed. In some embodiments, the emission areas EA1, EA2, and EA3 may correspond to red, green, and blue sub-pixels, respectively. In some cases, the display device may include an additional emission area configured to emit white light.

The encapsulation film TFE may be disposed on the light emitting element layer EML. The encapsulation film TFE may include at least one inorganic film and at least one organic film for encapsulating the light emitting element layer. For example, the encapsulation film TFE may include a multilayer stacked structure configured to prevent penetration of oxygen and moisture.

The optical member may include an lens assembly 230 disposed between a first base substrate 210 and a second base substrate 220. The lens assembly 230 may include a plurality of lenses 231. The optical member may include a filler layer 240 disposed between the first base substrate 210 and the second base substrate 220. For example, FIGS. 7 and 8 illustrate that the filler layer 240 is disposed on the lens assembly 230, but an embodiment of the present disclosure is not necessarily limited thereto. For example, light passing through the display panel may also pass through the filler layer 240 and then pass through the lens assembly 230. In addition, the lens 231 in the lens assembly 230 is convex in the fourth direction (e.g., in the W-axis direction), but embodiments of the present disclosure are not necessarily limited thereto. In some embodiments, the lenses 231 may be concave, cylindrical, or aspherical to provide various refraction characteristics.

As described above, since a refractive index range of a material having refractive index anisotropy in the lens 231 and a refractive index value of the filler layer 240 are adjusted, the refractive index range can be determined based on the presence or absence of a difference in refractive index between the lens 231 and the filler layer 240. Accordingly, an upper and lower relationship between the lens assembly 230 and the filler layer 240, a convex direction of the lens 231, and the other characteristics can be modified.

Each of the first base substrate 210, the second base substrate 220, a third base substrate 260, and a fourth base substrate 270 may include a material through which light may be transmitted, such as glass or plastic.

A polarization control unit 250 may be formed on a rear surface of the first base substrate 210 or a front surface of the display panel. For example, the polarization control unit 250 may be disposed between a lower surface of the first base substrate 210 and an upper surface of the display panel (or an upper surface of encapsulation film TFE of the display panel). A polarization control unit 250 is configured to switch and output 2D image display light of the display panel to a path PDX in the first linear polarization direction or a path PDY in the second linear polarization direction. The polarization control unit 250 may include a first driving electrode 251, a second driving electrode 252, and driving liquid crystals 254 disposed between the first driving electrode 251 and the second driving electrode 252. The polarization control unit 250 may further include a polarizing member 257 disposed on the display panel. For example, the polarization control unit 250 may include first driving electrode 251, driving liquid crystals 254, second driving electrode 252, and polarizing member 257 sequentially stacked.

The polarization control unit 250 may allow light incident on the path PDX in the first linear polarization direction through the polarizing member 257 to be maintained at and pass through the path PDX in the first linear polarization direction or to be switched to and pass through the path PDY in the second linear polarization direction. Accordingly, the polarization control unit 250 may selectively maintain or rotate the polarization state of the transmitted light depending on an applied voltage.

The polarization control unit 250 may allow the light incident on the path PDX in the first linear polarization direction through the polarizing member 257 to be switched to and pass through a path in any linear polarization direction between the first linear polarization direction and the second linear polarization direction.

For example, the first linear polarization direction may be parallel to the first direction (e.g., the X-axis direction) and the second linear polarization direction may be parallel to the second direction (e.g., the Y-axis direction), but an embodiment of the present disclosure is not necessarily limited thereto.

At least some components of the first driving electrode 251, driving liquid crystals 254, second driving electrode 252of the polarization control unit 250 may be disposed between the third base substrate 260 and the fourth base substrate 270. The polarizing member 257 of the polarization control unit 250 may be disposed between the display panel and the third base substrate 260. This configuration enables the polarization control unit 250 to be modularly integrated within the optical stack.

The first driving electrode 251 may be disposed between the third base substrate 260 and the fourth base substrate 270. A voltage may be applied to the first driving electrode 251.

The second driving electrode 252 may be disposed between the third base substrate 260 and the first driving electrode 251. The second driving electrode 252 may be parallel to the first driving electrode 251. A shape of the second driving electrode 252 may correspond to a shape of the first driving electrode 251. A voltage may be applied to the second driving electrode 252. The driving liquid crystals 254 may adjust a linear polarization direction of light based on a voltage difference between the voltage applied to the first driving electrode 251 and the voltage applied to the second driving electrode 252. In some cases, the first driving electrode 251 and the second driving electrode 252 may be patterned in various configurations such as stripe, grid, or pixelated configurations.

The polarizing member 257 may be disposed between the display panel (or an upper surface of encapsulation film TFE of the display panel) and the third base substrate 260. The light emitted from the display panel may vibrate in all directions. The polarizing member 257 may pass only light vibrating in a specific direction among the light emitted from the display panel and block remaining polarization compoennts. In an embodiment, the polarizing member 257 may pass only light having the path PDX in the first linear polarization direction among the light emitted from the display panel, but embodiments of the present disclosure are not necessarily limited thereto.

The driving liquid crystals 254 may be disposed between the first driving electrode 251 and the second driving electrode 252. The driving liquid crystal 254 may include a liquid crystal that is a birefringent material. An arrangement of the driving liquid crystals 254 may be changed based on the difference between the voltages applied to the first driving electrode 251 and the second driving electrode 252. The driving liquid crystal 254 may be a twisted nematic (TN) liquid crystal.

Referring to FIG. 7, a difference between the voltage applied to the first driving electrode 251 and the voltage applied to the second driving electrode 252 during a two-dimensional image display period may be less than or equal to a predetermined threshold value. The driving liquid crystal 254 may maintain the linear polarization direction of the light incident with the path PDX in the first linear polarization direction. The light passing through the driving liquid crystal 254 may still have the path PDX in the first linear polarization direction. In this case, the viewer may perceive a high-resolution two-dimensional image without refractive distortion.

Referring to FIG. 8, a difference between the voltage applied to the first driving electrode 251 and the voltage applied to the second driving electrode 252 during a three-dimensional image display period may be greater than or equal to a predetermined threshold value. The driving liquid crystal 254 may switch the linear polarization direction of the light incident with the path PDX in the first linear polarization direction. The light passing through the driving liquid crystal 254 may have the path PDY in the second linear polarization direction. Accordingly, the viewer may perceive a stereoscopic three-dimensional image from refraction in the lens assembly.

Referring to FIGS. 7 and 8, the first base substrate 210, the second base substrate 220, and the lens assembly 230 may be disposed on the fourth base substrate 270. The lens assembly 230 may be parallel and formed in the shape of a lens sheet. The polarization control unit 250 may be disposed in a stacked configuration overlapping the lens assembly 230 formed in the shape of the lens sheet.

The lens assembly 230 may include a plurality of lenses 231. In some cases, the lenses 231 may be arranged as a periodic array, a slanted array, or other arrangements to achieve different light field viewing characteristics.

Light passing through the plurality of lenses 231 may experience a refractive index of the lens 231 in the major axis direction, a refractive index of the lens 231 in the minor axis direction, or various refractive indices of the lens 231 in directions between the major axis direction and the minor axis direction based on an arrangement of birefringent materials (e.g., liquid crystals, slits, etc.) within the plurality of lenses 231. The intermediate refractive indices may be smaller than the refractive index of the lens 231 in the major axis direction and greater than the refractive index of the lens 231 in the minor axis direction, but embodiments of the present disclosure are not necessarily limited thereto. For example, the intermediate refractive indices may also be smaller than the refractive index of the lens 231 in the minor axis direction and greater than the refractive index of the lens 231 in the major axis direction.

In an embodiment, the major axis direction of the lens 231 may be parallel to the second direction (e.g., the Y-axis direction), and the minor axis direction of the lens 231 may be parallel to the first direction (e.g., the X-axis direction). In addition, a refractive index of the filler layer 240 disposed on the lens 231 may be the same as the refractive index of the lens 231 in the minor axis direction and smaller than the refractive index of the lens 231 in the major axis direction, but embodiments of the present disclosure are not necessarily limited thereto. For example, the major and minor axis directions may be oriented at arbitrary angles with respect to the X-axis and Y-axis.

Referring to FIG. 7, light passing through the driving liquid crystal 254 may have the path PDX in the first linear polarization direction, and the first linear polarization direction may coincide with or be parallel to the first direction (e.g., the X-axis direction). Accordingly, the light passing through the driving liquid crystal 254 may experience the refractive index of the lens 231 in the minor axis direction. Since the refractive index of the lens 231 in the minor axis direction is the same as the refractive index of the filler layer 240, the light passing through the driving liquid crystal 254 may travel straight without being refracted at the interface between the lens 231 and the filler layer 240. The two-dimensional image may be displayed from the second type of light field display without refraction. This configuration enables the second type of light field display to provide high-resolution 2D imaging.

Referring to FIG. 8, light passing through the driving liquid crystal 254 may have the path PDY in the second linear polarization direction, and the second linear polarization direction may coincide with or be parallel to the second direction (e.g., the Y-axis direction). Accordingly, the light passing through the driving liquid crystal 254 may experience the refractive index of the lens 231 in the major axis direction. Since the refractive index of the lens 231 in the major axis direction is greater than the refractive index of the filler layer 240, the light passing through the driving liquid crystal 254 may be refracted at the interface between the lens 231 and the filler layer 240. The three-dimensional image may be displayed from the second type of light field display by the refracted light. The refracted light may move toward a first view area V1, a second view area V2, and a third view area V3 based on the mapped viewing angles. Accordingly, the viewer may perceive stereoscopic depth by receiving different image information from each of the first view area V1, the second view area V2, and the third view area V3.

The filler layer 240 may be disposed on the plurality of lenses 231. The second base substrate 220 may be disposed on the filler layer 240. In some cases, the filler layer 240 is disposed between the first base substrate 210 and the second base substrate 220.

The filler layer 240 may include a transparent material through which light can be transmitted. As an example, the filler layer 240 may include an isotropic polymer material.

The refractive index of the filler layer 240 may be the same as a refractive index of the plurality of lenses 231 in the minor axis direction. The refractive index of the filler layer 240 may be smaller than a refractive index of the liquid crystal included in the lens 231 in the major axis direction. Accordingly, light passing through the plurality of lenses 231 may or may not be refracted at the interface.

Referring to FIGS. 5 and 6, in the first type of light field display, the display panel may include a substrate SUB, a thin film transistor layer TFTL, a light emitting element layer EML, and an encapsulation film TFE. Components having substantially the same functions as those of the second type of light field display described above will be denoted by the same reference numerals, and the difference are described. Accordingly, this refractive index relationship allows selective control of refraction based on the polarization state of incident light.

A polarizing member 257 may be disposed between the display panel and a first base substrate 210. The light emitted from the display panel may vibrate in all directions. The polarizing member 257 may pass light vibrating in a specific direction among the light emitted from the display panel and block remaining polarization components. In an embodiment, the polarizing member 257 may pass light having the path PDX in the first linear polarization direction among the light emitted from the display panel, but embodiments of the present disclosure are not necessarily limited thereto.

A third driving electrode 232 may be disposed between the first base substrate 210 and a second base substrate 220, and a fourth driving electrode 233 may be disposed between the first base substrate 210 and the third driving electrode 232. An lens assembly 230 including lenses 231 may be disposed between the third driving electrode 232 and the fourth driving electrode 233. A filler layer 240 may be disposed on the lens assembly 230, but as described above, an upper and lower relationship between the lens assembly 230 and the filler layer 240 is not necessarily limited to that illustrated in FIGS. 5 and 6. In some cases, the filler layer 240 may alternatively be disposed below the lens assembly 230. In one aspect, the first base substrate 210, the fourth driving electrode 233, the lens assembly 230 including lenses 231, the filler layer 240, the third driving electrode 232, and the second base substrate 220 may be sequentially stacked.

Voltages may be applied to the third driving electrode 232 and the fourth driving electrode 233, and the lens 231 may include liquid crystals that are birefringent materials. An arrangement, an alignment direction, and other characteristics of the liquid crystals in the lens 231 may be changed based on a difference between the voltages applied to the third driving electrode 232 and the fourth driving electrode 233.

Referring to FIG. 5, a difference between the voltage applied to the third driving electrode 232 and the voltage applied to the fourth driving electrode 233 during a two-dimensional image display period may be less than or equal to a predetermined threshold value. Light passing through the display panel may have a path PDX in the first linear polarization direction. The first linear polarization direction may coincide with or be parallel to a minor axis direction of the liquid crystal in the lens 231. Since the light passes through the light crystal experiences a refractive index of the liquid crystal in the minor axis direction and the refractive index of the liquid crystal in the minor axis direction is the same as a refractive index of the filler layer 240, the light might not be refracted at an interface. The two-dimensional image may be displayed from the first type of light field display without refraction. Accordingly, high-resolution two-dimensional images can be displayed by the display device.

Referring to FIG. 6, a difference between the voltage applied to the third driving electrode 232 and the voltage applied to the fourth driving electrode 233 during a three-dimensional image display period may be grater than or equal to a predetermined threshold value. Light passing through the display panel may have a path PDX in the first linear polarization direction. The first linear polarization direction may coincide with or parallel to a major axis direction of the liquid crystal in the lens 231. Since the light passes through the light crystal experiences a refractive index of the liquid crystal in the major axis direction and the refractive index of the liquid crystal in the major axis direction is greater than the refractive index of the filler layer 240, light may be refracted at the interface. The three-dimensional image may be displayed from the first type of light field display from the refracted light. The refracted light may move toward a first view area V1, a second view area V2, and a third view area V3 based on mapped viewing angles. Accordingly, the viewer may perceive stereoscopic depth information as different image data is directed toward difference viewing areas.

In some cases, the refractive index of the filler layer 240 is the same as the refractive index of the lens 231 or the liquid crystal in the lens 231 in the minor axis direction. The refractive index of the filler layer 240 is smaller than the refractive index of the lens 231 or the liquid crystal in the lens 231 in the major axis direction. In addition, the linear polarization direction is specified in the first type and the second type of light field displays. In addition, the two-dimensional image is displayed in the first type of light field display when the voltages are not applied to the third driving electrode 232 and the fourth driving electrode 233, and the three-dimensional image is displayed in the first type of light field display when the voltages are applied to the third driving electrode 232 and the fourth driving electrode 233. In addition, the two-dimensional image is displayed in the second type of light field display when the voltages are not applied to the first driving electrode 251 and the second driving electrode 252 and the three-dimensional image is displayed in the second type of light field display when the voltages are applied to the first driving electrode 251 and the second driving electrode 252. These operational illustrate representative driving modes but do not necessarily limit the scope of the present disclosure.

However, this is only an example for convenience of explanation, uniformity, and the like, and variables such as a refractive index range based on birefringence characteristics of the liquid crystal, a refractive index value of the filler layer, and a linear polarization direction of light passing through individual components may be further modified to enhance the image quality of the two-dimensional and three-dimensional images.

For example, in the first type of light field display, the major axis direction and the minor axis direction of the liquid crystal in the lens 231 may be changed, and in the second type of light field display, the linear polarization direction of the light passing through the display panel may be changed. For example, the first type light field display achieves switching by modifying the optical axis orientation of the lens, and the second type light field display achieves switching by modifying the polarization state of incident light.

Referring to FIG. 4, in the always-on light field display, a linear polarization direction of light, and an alignment direction of liquid crystals might not be changed, and a three-dimensional image may be displayed. In the always-on light field display, the first data may be input to the light emitting element corresponding to the first viewing angle and the light emitting element corresponding to the second viewing angle to display the two-dimensional image. The light emitted from the light emitting element corresponding to the first viewing angle is refracted even when the two-dimensional image is displayed, and the light emitted from the light emitting element corresponding to the second viewing angle is mapped is also refracted. However, the viewing angles are divided, and resolution of the two-dimensional image may be less than or equal to 50%, and thus, a resolution deterioration problem may occur. For example, in the always-on light field display, light is always refracted, and thus, a three-dimensional image is displayed.

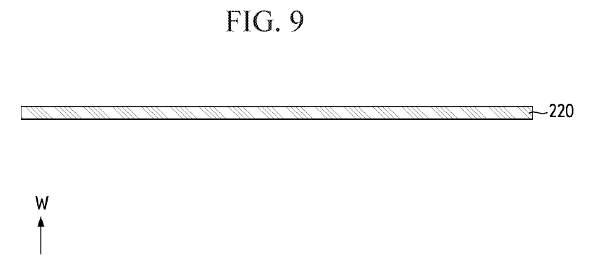

FIGS. 9-13 are cross-sectional views illustrating a manufacturing process of a light field display. For example, the process sequentially illustrates preparation of the base substrates, deposition of a filler layer, lamination of substrates, injection of liquid crystals, and formation of the lens assembly.

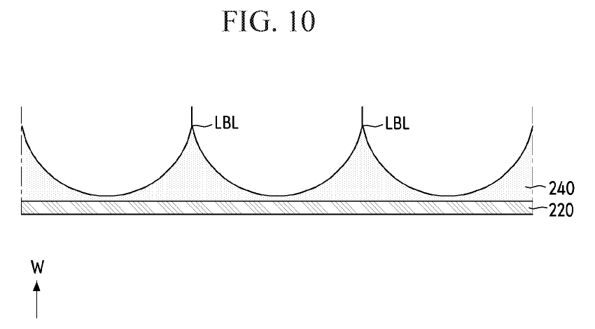

Referring to FIGS. 9 and 10, the filler layer 240 may be formed on the second base substrate 220. The filler layer 240 may provide a frame for forming the lens assembly 230 or the lenses 231 at a subsequent stage of display device fabrication. Accordingly, the filler layer 240 may be designed and formed to include a boundary portion LBL of the lens 231 prior to liquid crystal injection. The filler layer 240 may be patterned using various molding techniques, etching, techniques, and photolithography.

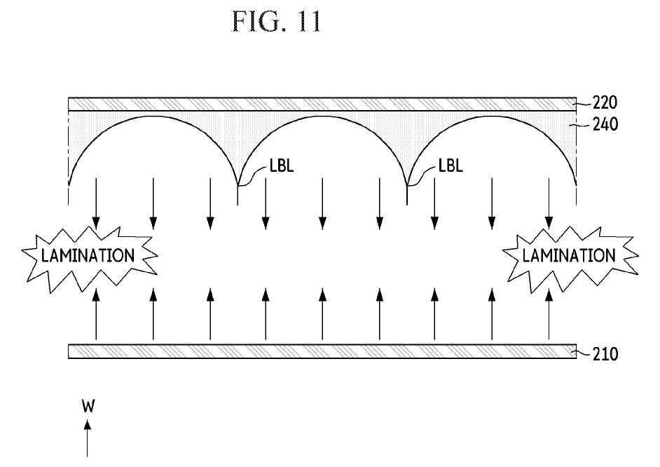

Referring to FIG. 11, the second base substrate 220 on which the filler layer 240 is formed may be laminated with the first base substrate 210. For example, the lamination process may include the use of optical adhesive layers, thermal compression bonding, or various curing methods.

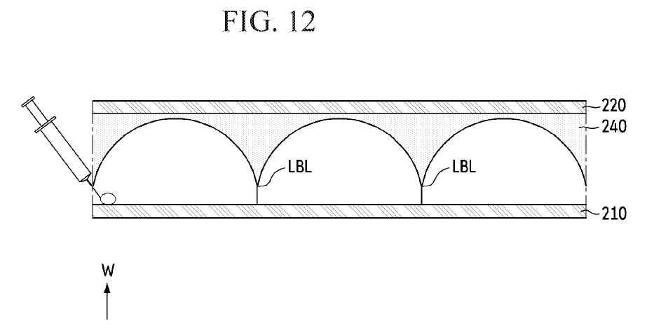

Referring to FIG. 12, liquid crystals may be injected into cavities defined by the filler layer 240 to form the lens 231.

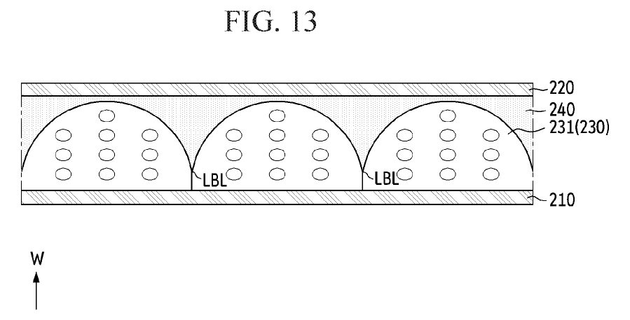

Referring to FIG. 13, the lens 231 and the filler layer 240 disposed between the first base substrate 210 and the second base substrate 220 may be formed.

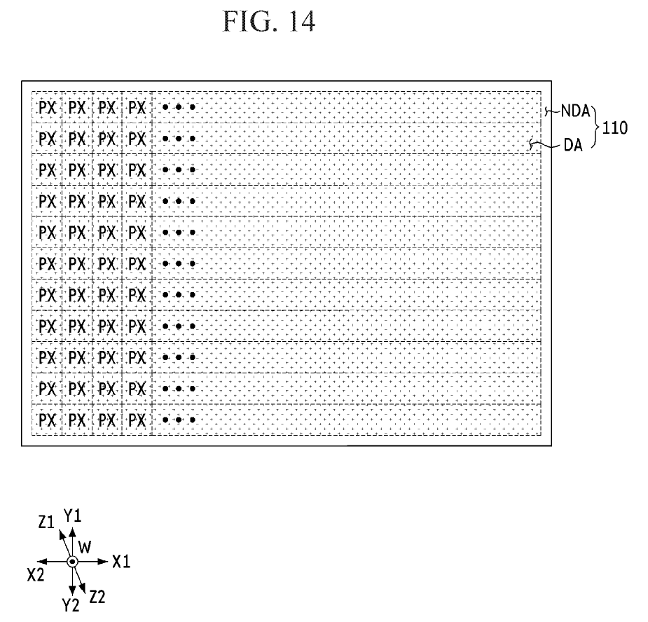

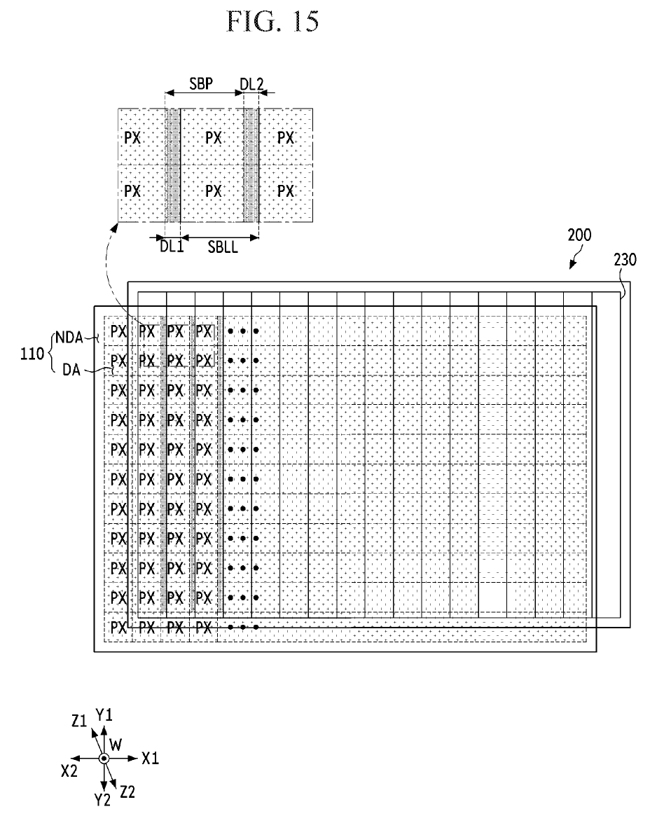

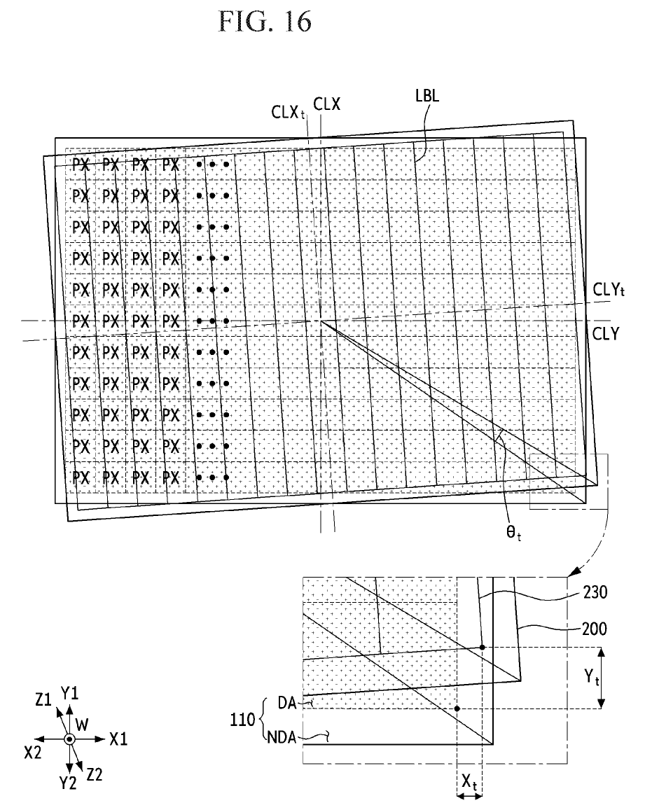

FIG. 14 is a plan view illustrating a display panel. FIG. 15 is a view illustrating a moiré phenomenon occurring due to an lens assembly disposed on the display panel. FIG. 16 is a view illustrating a tilting arrangement the lens assembly disposed on the display panel to prevent the moiré phenomenon.

Referring to FIG. 14, the display panel 110 may include the display area DA and the non-display area NDA surrounding the display area DA. A plurality of pixels PX may be disposed in the display area DA. Each of the plurality of pixels PX may include a first sub-pixel displaying a first color, a second sub-pixel displaying a second color, and a third sub-pixel displaying a third color. Each of the first color, the second color, and the third color may be a red color, a green color, and a blue color. For example, the first color, the second color, and the third color are different from each other. As an example, the first color may be a red color, the second color may be a green color, and the third color may be a blue color, but embodiments of the present disclosure are not necessarily limited thereto. In some embodiments, additional sub-pixels may be included, such as a white sub-pixel configured to emit light having a white color.

Referring to FIG. 15, the optical member 200 may be disposed on the display panel 110. The optical member 200 may include the lens assembly 230.

Referring to an enlarged view of FIG. 15, the plurality of pixels PX may be disposed at a first interval SBP, and a plurality of lenses in the lens assembly 230 disposed on the optical member 200 may be disposed at a second interval SBLL. The first interval SBP may be the same as or different from the second interval SBLL. In some cases, an offset between the intervals SBP and SBLL may introduce spatial interference patterns observable as moiré phenomenon.

For example, a boundary portion between the plurality of pixels PX disposed at the first interval SBP might not overlap a boundary portion between the plurality of lenses disposed at the second interval SBLL. For example, the first interval SBP may be different from the second interval SBLL. As an example, the boundary portion between the plurality of pixels PX and the boundary portion between the plurality of lenses may be misaligned or offset, such that a plurality of gaps having different sizes may be generated. For example, the boundary portion between the plurality of pixels PX and the boundary portion between the plurality of lenses may be shifted relative to one another, such that a first boundary portion gap DL1 and a second boundary portion gap DL2 may be generated. The first boundary portion gap DL1 and the second boundary portion gap DL2 may contribute to moiré interference and degradation of display uniformity

The first boundary gap DL1 and the second boundary gap DL2 may be smaller than the first interval SBP and the second interval SBLL. An interaction between patterns corresponding to the first boundary gap DL1 and an interaction between patterns corresponding to the second boundary gap DL2 may cause a moiré phenomenon. The moiré phenomenon may occur due to an interaction between a plurality of regular patterns when the plurality of regular patterns overlap each other. The moiré phenomenon may occur when attaching the optical member 200 to the display panel 110, and may deteriorate display quality of the display device.

Referring to FIG. 16, in order to prevent the display quality from the moiré phenomenon, the optical member 200 may be attached onto the display panel 110 in a tilted arrangement by a predetermined angle θₜ. In some cases, the predetermined angle θₜ may be referred to as the tilt angle. In some embodiments, the display panel 110 including a plurality of pixels may be attached to the lens assembly 230 at a tilt angle with respect to the display panel 110. This tilted configuration of the lens assembly 230 and the display panel 110 suppresses the moiré phenomenon and enhances image quality in the three-dimensional images. To support accurate placement of the lens assembly 230 with the tilted configuration, a first base substrate 210 is disposed between the display panel 110 and the lens assembly 230, and a plurality of lens alignment marks (e.g., lower plate lens alignment marks DAM1, DAM2, and DAM3 described with reference to FIG. 7) are formed on the first base substrate 210. The alignment marks are aligned with the tilt angle so that, during lamination, the lens assembly 230 can be attached in the tilted orientation without requiring separate tilt adjustment.

The boundary portion LBL of the lens tilted by the predetermined angle θₜ may be parallel to a third direction (e.g., a Z1-axis direction or a Z2-axis direction). A plane may be defined from a first direction (e.g., an X1-axis direction or an X2-axis direction) and a second direction (e.g., a Y1-axis direction or a Y2-axis direction) crossing the first direction (e.g., the X1-axis direction or the X2-axis direction). In some cases, the first direction and the second direction are perpendicular to each other. The third direction may be defined as a direction between the first direction (e.g., the X1-axis direction or the X2-axis direction) and the second direction (e.g., the Y1-axis direction or the Y2-axis direction) on the above-described plane. The boundary portion LBL of the lens may be parallel to the third direction (e.g., the Z1-axis direction or the Z2-axis direction). This geometrical relationship ensures that the tilted orientation of the lens boundaries distributes periodic overlap with the pixel matrix more evenly, thereby mitigating moiré interference.

During the manufacturing process, the predetermined angle θₜ at which the moiré phenomenon is minimized may be derived while tilting the optical member 200. In some cases, the optical member 200 tilted by the predetermined angle θₜ was attached onto the display panel 110, using various method such as lamination, adhesive bonding, or precision alignment.

A plurality of lenses included in a plurality of lens assembly 230 disposed in the optical member 200 may be disposed with the boundary portion LBL, and the boundary portion LBL may be disposed between the plurality of lenses. The boundary portion LBL of the lens may be defined between the plurality of lenses. One side of the optical member 200 may be parallel to the boundary portion LBL of the lens, and when the optical member 200 is tilted by the predetermined angle θₜ, the boundary portion LBL of the lens may be tilted by the predetermined angle θₜ. The pixels PX may be disposed in a matrix form, and the boundary portion between the pixels PX may include a boundary portion extending in the first direction (e.g., the X1-axis direction or the X2-axis direction) and a boundary portion extending in the second direction (e.g., the Y1-axis direction or the Y2-axis direction). When the predetermined angle θₜ is an acute angle, the boundary portion between the pixels PX may form the predetermined angle θₜ with the boundary portion extending in the second direction (e.g., the Y1-axis direction or the Y2-axis direction). Accordingly, angular misalignment between pixel rows and lens boundaries may prevent direct overlaps.

For example, a first central axis CLY extending from the display panel 110 in the first direction and a second central axis CLX extending from the display panel 110 in the second direction crossing the first direction may be defined. For example, the first direction may be the X-axis direction, and the second direction may be the Y-axis direction. The first direction and the second direction may be orthogonal (or perpendicular) to each other, but an embodiment of the present disclosure is not necessarily limited thereto. In addition, a third central axis CLYₜ extending from the optical member 200 in the first direction and a fourth central axis CLXₜ extending from the optical member 200 in the second direction may be defined. These central axes provide reference geometry for aligning the optical member 200 with the display panel 110 during tilted arrangement.

In a state where the predetermined angle θₜ capable of minimizing the moiré phenomenon is computed, a distance between a reference point of the display panel 110 and a reference point of the optical member 200 may be calculated to attach the lens formed on the second base substrate and the first base substrate to each other at the predetermined angle θₜ. The distance between the reference point of the display panel 110 and the reference point of the optical member 200 may be divided into a first distance Xₜ in the first direction (e.g., the X1-axis direction or the X2-axis direction) and a second distance Yₜ in the second direction (e.g., the Y1-axis direction or the Y2-axis direction). The first distance Xₜ and the second distance Yₜ may be computed by applying a cosine law or similar trigonometric functions to the predetermined angle θₜ and distances between the reference points and central portions. In some cases, since the predetermined angle θₜ minimizing the moiré phenomenon a small value, the distance between the reference points derived by the predetermined angle θₜ may be used for accurate attachment between the lens formed on the second base substrate and the first base substrate.

However, when the lens is formed using only the first distance Xₜ and the second distance Yₜ between the reference points, an error in the manufacturing process may occur, the time required for the manufacturing process may be undesirably increased.

Accordingly, embodiments of the present disclosure provide an alignment mark capable of accurately tilting and forming the optical member 200 using the predetermined angle θₜ to minimize the moiré phenomenon. The alignment mark serves as a visual or lithographic reference that allows precise control of tilt orientation during fabrication, thereby reducing dependency on calculations using the first distance Xₜ and the second distance Yₜ.

Referring to the aforementioned manufacturing process, the filler layer may be manufactured on the second base substrate to form the frame of the lens assembly 230 and then attached to the first base substrate. When the filler layer is formed on the second base substrate in a state in which the filler layer is tilted by the predetermined angle θₜ and accurate lamination between the second base substrate and the first base substrate is performed, a misalignment error may be reduced. Since the optical member 200 includes the lens assembly 230 in an already tilted state, optical member 200 can be attached onto the display panel 110 without additional tilt arrangement. This pre-tilt manufacturing approach simplifies assembly, shortens process time, and ensures consistent suppression of moiré phenomenon across the display device.

The display device a may be formed by attaching the lens assembly 230 or the lens formed in a state in which the lens is already tilted by the predetermined angle θₜ onto the display panel 110 without the need to separately tilt and attach the optical member 200. In this process, accurate lamination between the tilted lens formed on the second base substrate and the first base substrate may ensure alignment accuracy and prevent residual moiré phenomenon. In some embodiments, these alignment marks may be formed on the substrates to ensure high-precision lamination.

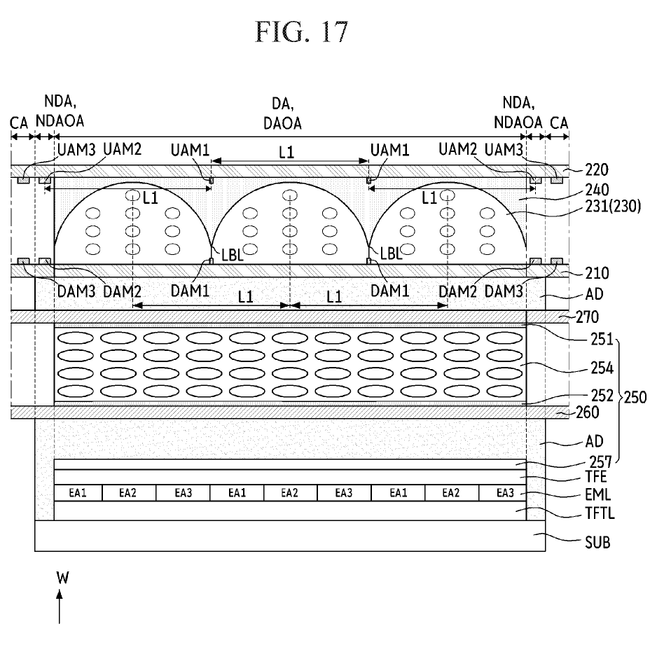

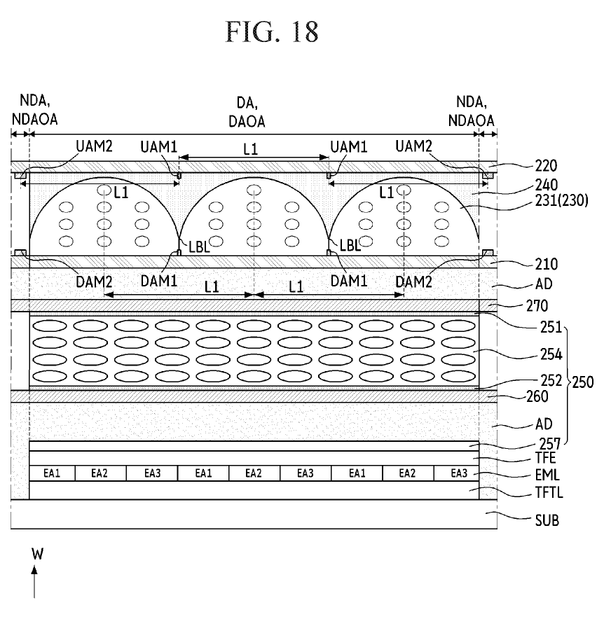

FIG. 17 is a cross-sectional view illustrating a display device according to another embodiment of the present disclosure. FIG. 18 is a cross-sectional view illustrating a display device according to another embodiment of the present disclosure.

Referring to FIGS. 17 and 18, the display device may be formed by attaching the display panel and the first base substrate 210 to each other using an adhesive AD. In the always-on light field display or the first type of light field display of the switchable light field displays, a separate component might not be disposed between the display panel and the first base substrate 210. In the second type of light field display of the switchable light field displays, the third base substrate 260, the fourth base substrate 270, and the driving liquid crystals 254 may be disposed between the display panel and the first base substrate 210. For example, the display panel and the third base substrate 260 may be attached to each other using an adhesive AD, and the fourth base substrate 270 and the first base substrate 210 may be attached to each other using an adhesive AD. The display panel may include the display area DA and the non-display area NDA.

In the display device according to an embodiment, the boundary portion LBL of the lens 231 is formed in a tilted state during a process of disposing the filler layer 240 on the second base substrate 220. In addition, since the filler layer 240 provides the boundary portion LBL of the lens 231, the boundary portion LBL of the lens 231 in the tilted state can be accurately aligned with the first base substrate 210 during lamination of the second base substrate 220 and the first base substrate 210. In some cases, the alignment marks may be employed at the non-display area NDA to ensure accurate registration of the tilted boundary portions LBL with the pixel matrix.

The display device may include a plurality of lens alignment marks to ensure accurate alignment. The lens alignment marks may include lower plate lens alignment marks DAM1, DAM2, and DAM3 adjacent to the first base substrate 210 and upper plate lens alignment marks UAM1, UAM2, and UAM3 adjacent to the second base substrate 220. The alignment marks may be configured in shapes such as cross patterns to facilitate automated lamination of the first base substrate 210 and the second base substrate 220.

In addition, a display overlap area DAOA overlapping the display area DA of the display panel in the fourth direction (e.g., the W-axis direction) and a non-display overlap area NDAOA overlapping the non-display area NDA of the display panel in the fourth direction (e.g., the W-axis direction) may be defined in the first base substrate 210 and the second base substrate 220. The non-display overlap area NDAOA may surround the display overlap area DAOA, and the display overlap area DAOA is disposed between the non-display overlap areas NDAOA in cross-sectional view. In some cases, the non-display overlap area NDAOA provides a location for forming alignment marks without interfering with the pixel matrix. In some cases, the lower plate lens alignment mark DAM2 and the and upper plate lens alignment mark UAM2 may be disposed in the non-display overlap areas NDAOA. In some cases, the lower plate lens alignment mark DAM1 and the and upper plate lens alignment mark UAM1 may be disposed in the display overlap area DAOA.

In the first base substrate 210 and the second base substrate 220, a cutting area CA may be further defined. The cutting area CA may surround the non-display overlap area NDAOA, and the non-display overlap area NDAOA and the display overlap area DAOA are disposed between the cutting areas CA in cross sectional view. The cutting area CA may be an area to be removed after a lamination process and/or an attachment process is completed (see FIG. 18). Accordingly, most of the alignment marks may be disposed in the cutting area CA. Because the cutting area CA is removed during the cutting process, most of the alignment marks formed in this region may also be removed. In some cases, the lower plate lens alignment mark DAM3 and the and upper plate lens alignment mark UAM3 may be disposed in the cutting area CA. Accordingly, alignment marks in NDAOA may be used as primary references during lamination, while marks in non-display overlap area DAOA are minimized or reduced in width to avoid visibility to a user or viewer.

The plurality of lens alignment marks may include first lens alignment marks DAM1 and UAM1 disposed in the display overlap area DAOA, second lens alignment marks DAM2 and UAM2 disposed in the non-display overlap area NDAOA, and third lens alignment marks DAM3 and UAM3 disposed in the cutting area CA. The first lens alignment marks DAM1 and UAM1, the second lens alignment marks DAM2 and UAM2, and the third lens alignment marks DAM3 and UAM3 may be divided into the upper plate lens alignment marks UAM1, UAM2, and UAM3 and the lower plate lens alignment marks DAM1, DAM2, and DAM3, respectively. By distributing alignment marks across display overlap area DAOA, non-display overlap area NDAOA, and cutting area CA, the first base substrate 210 nd the second base substrate 220 can be accurately and efficiently aligned.

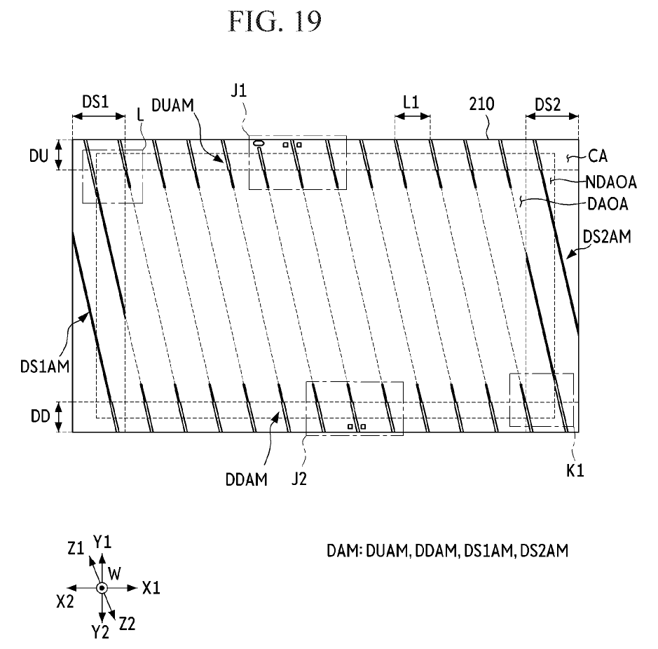

In some cases, the first lens alignment marks DAM1 and UAM1 are disposed in the display overlap area DAOA, and the second lens alignment marks DAM2 and UAM2 and the third lens alignment marks DAM3 and UAM3 are not disposed in the display overlap area DAOA. The first lens alignment marks DAM1 and UAM1, and the second lens alignment marks DAM2 and UAM2, and the third lens alignment marks DAM3 and UAM3 may need to be distinguished from each other. For example, widths of the first lens alignment marks DAM1 and UAM1 may be different from widths of the second lens alignment marks DAM2 and UAM2 and the third lens alignment marks DAM3 and UAM3. For example, the widths of the first lens alignment marks DAM1 and UAM1 may be smaller than the widths of the second lens alignment marks DAM2 and UAM2 and the third lens alignment marks DAM3 and UAM3. In an embodiment, the widths of the second lens alignment mark DAM2 and UAM2 may be substantially the same as the widths of the third lens alignment mark DAM3 and UAM3. The widths of the lens alignment marks are further described in detail with reference to partially enlarged views in FIGS. 19-27.

The lens alignment marks may be provided to accurately attach the boundary portions LBL of the lenses 231 provided by the filler layer 240 formed on the second base substrate 220 to the first base substrate 210. Therefore, the lens alignment marks may have substantially the same interval as the plurality of lenses 231 spaced apart from each other by a first interval L1. The plurality of lens alignment marks may also be disposed at the first interval L1.

To accurately laminate the first base substrate 210 and the second base substrate 220, the upper plate lens alignment marks UAM1, UAM2, and UAM3 and the lower plate lens alignment marks DAM1, DAM2, and DAM3 may overlap each other in the fourth direction (e.g., the W-axis direction). In addition, the upper plate lens alignment marks UAM1, UAM2, and UAM3 and the lower plate lens alignment marks DAM1, DAM2, and DAM3 may overlap the boundary portions LBL of the lenses 231 in the fourth direction (e.g., the W-axis direction). For example, since the lenses 231 are formed in the display overlap area DAOA, the first lens alignment marks DAM1 and UAM1 may overlap the boundary portions LBL of the lenses 231 in the fourth direction (e.g., the W-axis direction). This overlapping arrangement ensures that the predetermined angle θₜ (or the tilt angle) is maintained consistently across the entire lens array.

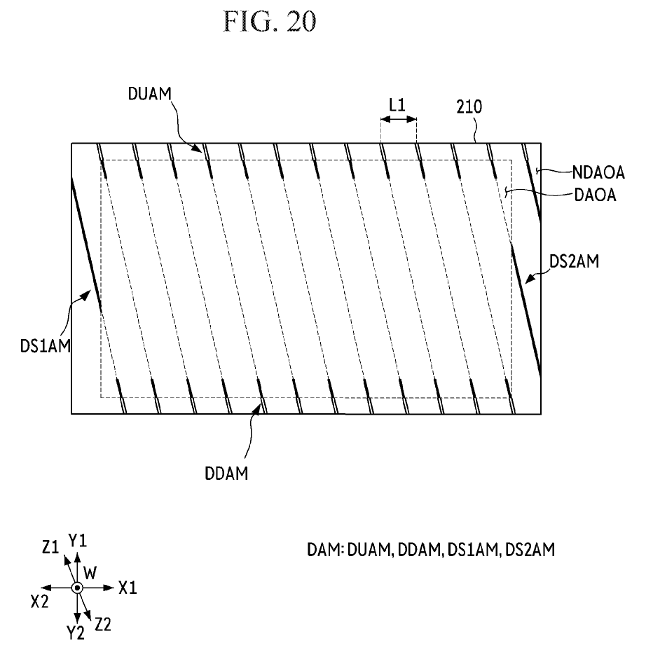

FIG. 19 is a plan view illustrating a lower plate lens alignment mark according to an embodiment of the present disclosure. FIG. 20 is a plan view illustrating a lower plate lens alignment mark according to an embodiment of the present disclosure.

Referring to FIGS. 19 and 20, an embodiment illustrates a state in which the cutting area CA is removed from the first base substrate 210. Other configurations are described when the cutting area CA is not removed, but an embodiment of the present disclosure is not necessarily limited thereto.

A lens alignment mark illustrated in FIGS. 19 and 20 may be a lower plate lens alignment mark DAM adjacent to the first base substrate 210. In plan view, the lower plate lens alignment mark DAM may include a first lens alignment mark, a second lens alignment mark, and a third lens alignment mark. These lens alignment marks may extend in the third direction (e.g., the Z1-axis direction or the Z2-axis direction).

Each of the display overlap area DAOA, the non-display overlap area NDAOA, and the cutting area CA may be divided into an upper portion DU, a lower portion DD, and a first side portion DS1, and a second side portion DS2 opposite to the first side portion DS1. The first lens alignment mark may be disposed in the display overlap area DAOA, but may be disposed in the upper portion DU and the lower portion DD of the display overlap area DAOA. The second lens alignment mark may be disposed in the non-display overlap area NDAOA, and may be disposed in the upper portion DU, the lower portion DD, the first side portion DS1, and the second side portion DS2 of the non-display overlap area NDAOA. The third lens alignment mark may be disposed in the upper portion DU, the lower portion DD, the first side portion DS1, and the second side portion DS2 of the cutting area CA.

For example, the lower plate lens alignment mark DAM may be divided into a lower plate upper lens alignment mark DUAM disposed in the upper portion DU, a lower plate lower lens alignment mark DDAM disposed in the lower portion DD, a first lower plate side portion lens alignment mark DS1AM disposed in the first side portion DS1, and a second lower plate side portion lens alignment mark DS2AM disposed in the second side portion DS2. Each of the lower plate upper lens alignment mark DUAM and the lower plate lower lens alignment mark DDAM may include a first lens alignment mark, a second lens alignment mark, and a third lens alignment mark. Eachof the first lower plate side portion lens alignment mark DS1AM and the second lower plate side portion lens alignment mark DS2AM may include a second lens alignment mark and a third lens alignment mark.

The first lens alignment mark may be disposed in a partial area of the upper portion DU and a partial area of the lower portion DD of the display overlap area DAOA. In some cases, the first lens alignment mark may be perceived by the viewer, where the first lens alignment mark is disposed in the display overlap area DAOA overlapping the display area DA may be disposed in a partial area of the display overlap area DAOA. In some embodiments, the first lens alignment mark may be made thinner or patterned with reduced optical density to minimize visibility in the display overlap area DAOA of the display device. In addition, when the lower plate lens alignment marks DAM overlap with corresponding upper plate lens alignment marks UAM, the boundary portions LBL of the lenses 231 provided by the filler layer 240 may be automatically aligned with respect to the pixel array of the display panel. This alignment ensures that the first and second base substrates can be accurately and efficiently aligned to reduce moiré phenomenon.

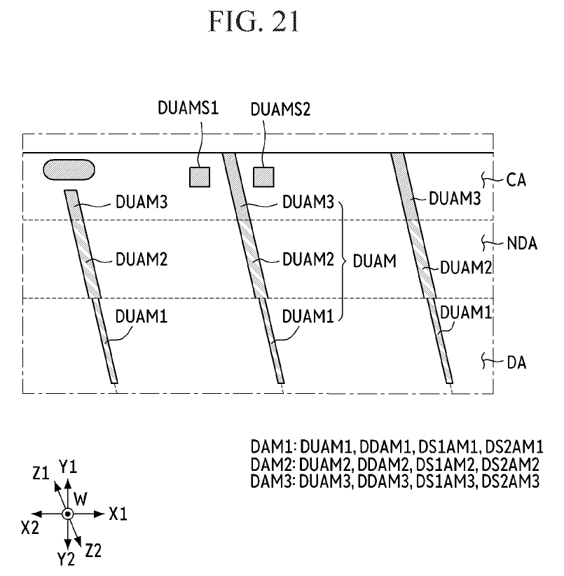

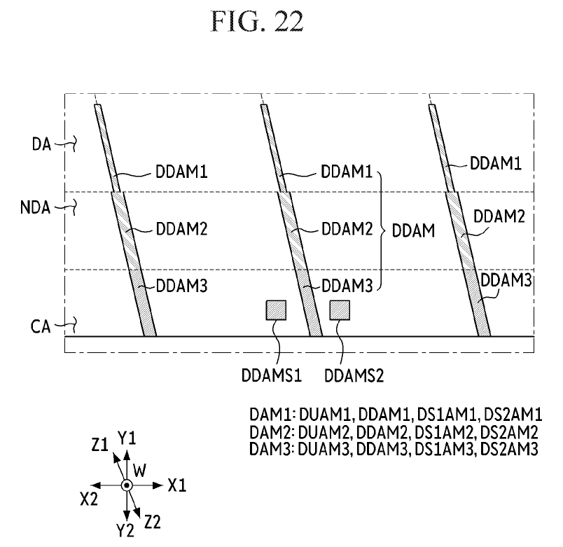

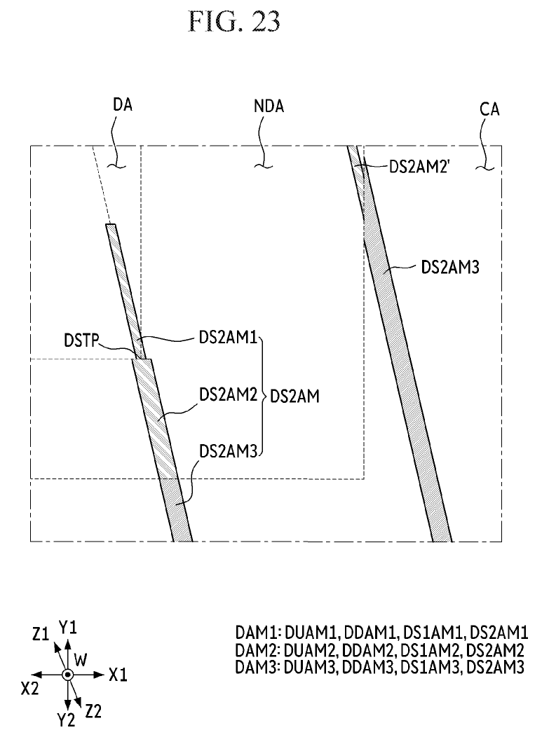

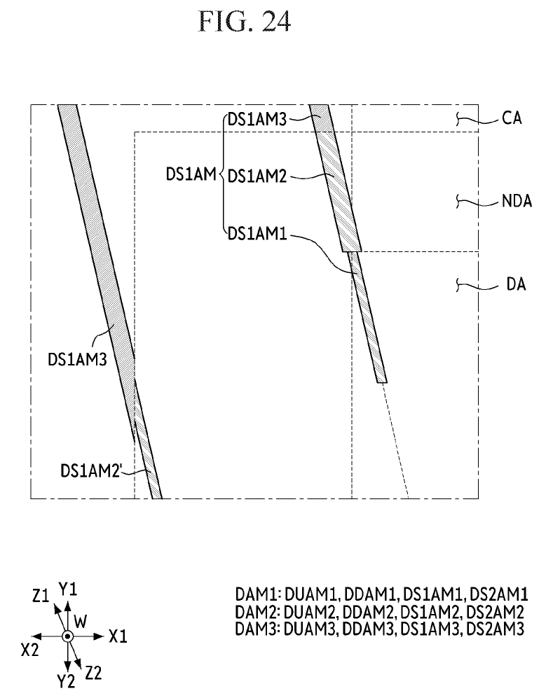

FIG. 21 is a partially enlarged view illustrating portion J1 of FIG. 19. FIG. 22 is a partially enlarged view illustrating portion J2 of FIG. 19. FIG. 23 is a partially enlarged view illustrating portion K1 of FIG. 19. FIG. 24 is a partially enlarged view illustrating portion L of FIG. 19.

Referring to FIG. 21, the lower plate upper lens alignment mark may be divided into the first lower plate upper lens alignment mark DUAM1, the second lower plate upper lens alignment mark DUAM2, and the third lower plate upper lens alignment mark DUAM3 as described above. A width of the first lower plate upper lens alignment mark DUAM1 may be smaller than widths of the second lower plate upper lens alignment mark DUAM2 and the third lower plate upper lens alignment mark DUAM3. In an embodiment, in order to ensure uniformity in the manufacturing process, the second lower plate upper lens alignment mark DUAM2 and the third lower plate upper lens alignment mark DUAM3 may have substantially the same width. The width may refer to a length of the alignment mark in the first direction (e.g., the X1-axis direction or the X2-axis direction).

In addition to the lens alignment marks, auxiliary lens alignment marks DUAMS1, DUAMS2, DDAMS1, DDAMS2 may be disposed in the cutting area CA. Accordingly, heights of the third lower plate upper lens alignment marks DUAM3 in a lower plate upper area may be different from each other. The height may refer to a length of the alignment mark in the second direction (e.g., the Y1-axis direction or the Y2-axis direction).

An auxiliary lens alignment mark may be further disposed in the cutting area CA. As described above, a tilt angle (e.g., the predetermined angle θₜ) of the lens 231 may be small. In order to accurately attach the first base substrate 210 and the second base substrate 220, lens alignment marks disposed in an upper area and corresponding lens alignment marks disposed in a lower area may need to accurately align with each other. Since the tilt angle is small, a lens alignment mark disposed in the upper area and a lens alignment mark corresponding to any one lens alignment mark and disposed in the lower area (hereinafter referred to as a “lens alignment mark set”) might not be accurately identified during the manufacturing process. The auxiliary lens alignment marks may be disposed so that the lens alignment mark may be accurately identified. The auxiliary lens alignment mark may be disposed in the cutting area CA, and may include a first auxiliary lens alignment mark DUAMS1 and a second auxiliary lens alignment mark DUAMS2 disposed with the lower plate upper lens alignment mark, and the lower plate upper lens alignment mark may be disposed between the first auxiliary lens alignment mark DUAMS1 and the second auxiliary lens alignment mark DUAMS2.

Referring to FIG. 22, the auxiliary lens alignment mark may include a third auxiliary lens alignment mark DDAMS1 and a fourth auxiliary lens alignment mark DDAMS2, which are provided to ensure that the lens alignment mark set may be accurately identified. The third auxiliary lens alignment mark DDAMS1 and the fourth auxiliary lens alignment mark DDAMS2 are disposed with the lower plate lower lens alignment mark DDAM, and the lower plate lower lens alignment mark DDAM is disposed between the third auxiliary lens alignment mark DDAMS1 and the fourth auxiliary lens alignment mark DDAMS2. The auxiliary marks serve as positional references to reduce errors caused by the small tilt angle of the lenses..

Referring to FIGS. 23 and 24, the display overlap area DAOA may be defined by a first side extending in the first direction (e.g., the X1-axis direction or the X2-axis direction) and a second side extending in the second direction (e.g., the Y1-axis direction or the Y2-axis direction). The first side and the second side may intersect to form a vertex, which serves as a reference point for aligning lens boundary portions.

The vertex may overlap a first lens alignment mark DS2AM1 or a second lens alignment mark DS2AM2 in the fourth direction (e.g., the W-axis direction). The first lens alignment mark and the second lens alignment mark may be distinguished from each other at a point DSTP overlapping the vertex, where the width of the alignment mark may change.

The point DSTP overlapping the vertex may provide an auxiliary reference that improves attachment accuracy during a lamination process of the first base substrate 210 and the second base substrate 220. For example, when the lens 231 includes a biconvex lens, precise alignment may be needed. By forming the point DSTP overlapping the vertex on a lower plate and attaching the first base substrate 210 and the second base substrate 220 so that the point DSTP overlaps a point USTP, the attachment accuracy in the display device can be increased. This approach achieves higher alignment precision and minimizes moiré phenomenon or resolution degradation.

According to an embodiment, a width of a second lens alignment mark DS2AM2’ may be different from a width of a third lens alignment mark DS2AM3. For example, the width of the second lens alignment mark DS2AM2’ formed at the same width as the first lens alignment mark DS2AM1 may be smaller than the width of the third lens alignment mark DS2AM3.

Referring to FIG. 24, the point overlapping the vertex may be formed in any one of the first side portion and the second side portion. Since the boundary portions LBL of the lenses 231 are formed at the first interval L1 and a predetermined tilt angle and a width of the display overlap area DAOA are fixed, forming vertex on both the first side portion and the second side portion may increase complexity of a design. According to an embodiment, by forming the point overlapping the vertex in one of the first side portion and the second side portion, the attachment accuracy can be increased and the complexity of the design can be reduced. However, the present disclosure is not necessarily limited thereto.

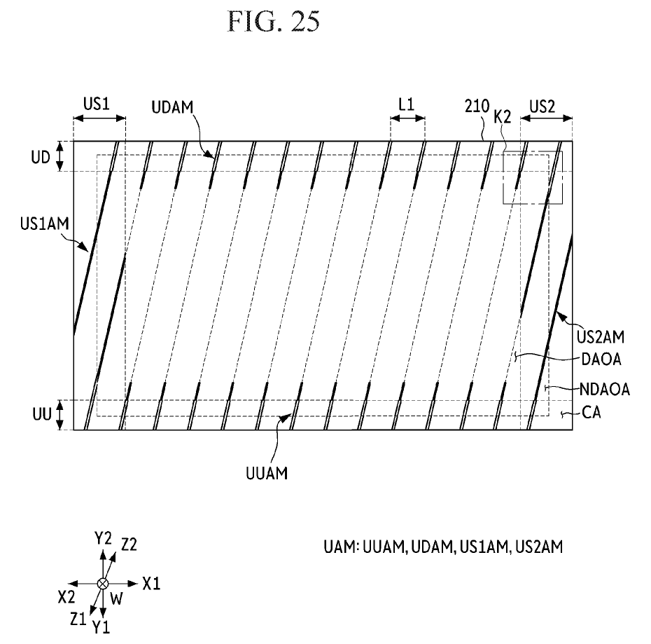

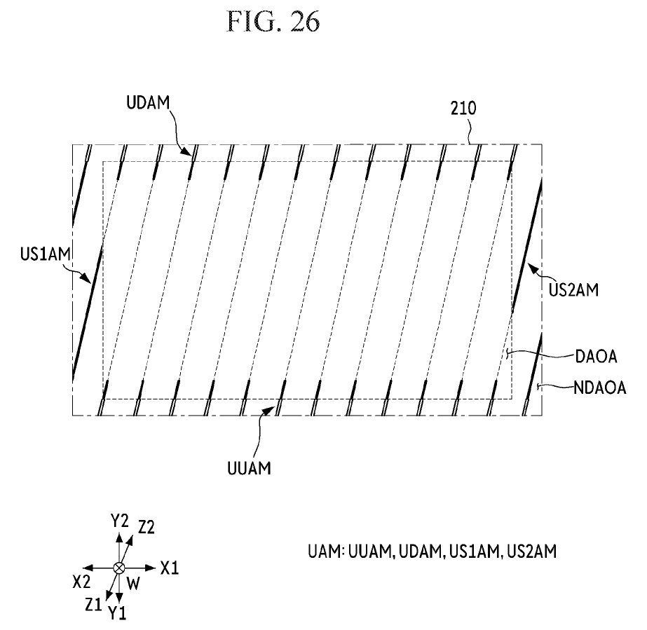

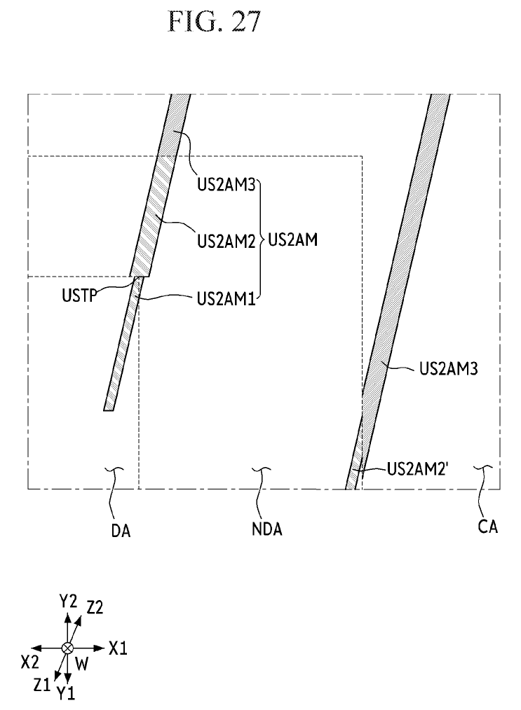

FIG. 25 is a plan view illustrating an upper plate lens alignment mark according to an embodiment of the present disclosure. FIG. 26 is a plan view illustrating an upper plate lens alignment mark according to an embodiment of the present disclosure. FIG. 27 is a partially enlarged view illustrating portion K2 of FIG. 25.

Referring to FIGS. 25 and 26, an embodiment illustrates a state in which the cutting area CA is removed from the first base substrate 210. Other configurations are described when the cutting area CA is not removed, but an embodiment of the present disclosure is not necessarily limited thereto.

A lens alignment mark illustrated in FIGS. 25 and 26 may be an upper plate lens alignment mark UAM more adjacent to the second base substrate 220. In a plan view, the upper plate lens alignment mark UAM may include a first lens alignment mark, a second lens alignment mark, and a third lens alignment mark. Such lens alignment marks may extend in the third direction (e.g., the Z1-axis direction or the Z2-axis direction).

Each of the display overlap area DAOA, the non-display overlap area NDAOA, and the cutting area CA may be divided into an upper portion UU, a lower portion UD, and a first side portion US1 and a second side portion US2 opposite to the first side portion US1. The first lens alignment mark may be disposed in the display overlap area DAOA, but may be disposed in the upper portion UU and the lower portion UD of the display overlap area DAOA. The second lens alignment mark may be disposed in the non-display overlap area NDAOA, the upper portion UU, the lower portion UD, the first side portion US1, and the second side portion US2 of the non-display overlap area NDAOA. The third lens alignment mark may be disposed in the upper portion UU, the lower portion UD, the first side portion US1, and the second side portion US2 of the cutting area CA.

For example, the upper plate lens alignment mark UAM may be divided into an upper plate upper lens alignment mark UUAM disposed in the upper portion UU, an upper plate lower lens alignment mark UDAM disposed in the lower portion UD, a first upper plate side portion lens alignment mark US1AM disposed in the first side portion US1, and a second upper plate side portion lens alignment mark US2AM disposed in the second side portion US2. Each of the upper plate upper lens alignment mark UUAM and the upper plate upper lens alignment mark UDAM may include a first lens alignment mark, a second lens alignment mark, and a third lens alignment mark. Each of the first upper plate side portion lens alignment mark US1AM and the second upper plate side portion lens alignment mark US2AM may include a second lens alignment mark and a third lens alignment mark.

Referring to the coordinate axes and the above description, the first base substrate 210 and the second base substrate 220 may be laminated with each other so that the upper plate upper lens alignment mark UUAM overlaps the lower plate upper lens alignment mark, the upper plate upper lens alignment mark UDAM overlaps the lower plate lower lens alignment mark, the first upper plate side portion lens alignment mark US1AM overlaps the first lower plate side portion lens alignment mark, and the second upper plate side portion lens alignment mark US2AM overlaps the second lower plate side portion lens alignment mark.

The first lens alignment mark may be disposed in a partial area of the upper portion UU and a partial area of the lower portion UD of the display overlap area DAOA. As described above, the first lens alignment mark may be perceived by the viewer, where the first lens alignment mark is disposed in the display overlap area DAOA overlapping the display area DA may be disposed in a partial area of the display overlap area DAOA.

Referring to FIG. 27, the display overlap area DAOA may be defined by a first side extending in the first direction (e.g., the X1-axis direction or the X2-axis direction) and a second side extending in the second direction (e.g., the Y1-axis direction or the Y2-axis direction). The first side and the second side may form a vertex by crossing each other.

The vertex may overlap a first lens alignment mark in the fourth direction (e.g., the W-axis direction). The vertex may overlap a second lens alignment mark in the fourth direction (e.g., the W-axis direction). The first lens alignment mark and the second lens alignment mark may be different and distinguished from each other at a point USTP overlapping the vertex, and a width of a lens alignment mark may be changed based on the vertex.

The point USTP overlapping the vertex may serve as an auxiliary function that enhances the attachment accuracy in a lamination process between the first base substrate 210 and the second base substrate 220. For example, when the lens 231 includes a biconvex lens, precise alignment may be needed. By forming the point USTP overlapping the vertex on the upper plate and attaching the first base substrate 210 and the second base substrate 220 so that the point USTP overlaps the point DSTP the attachment accuracy in the display device can be increased. This approach achieves higher alignment precision and minimizes moiré phenomenon or resolution degradation.

According to an embodiment, a width of a second lens alignment mark US2AM2’ may be different from a width of a third lens alignment mark US2AM3. For example, the width of the second lens alignment mark US2AM2’ formed at the same width as the first lens alignment mark US2AM1 may be smaller than the width of the third lens alignment mark US2AM3.

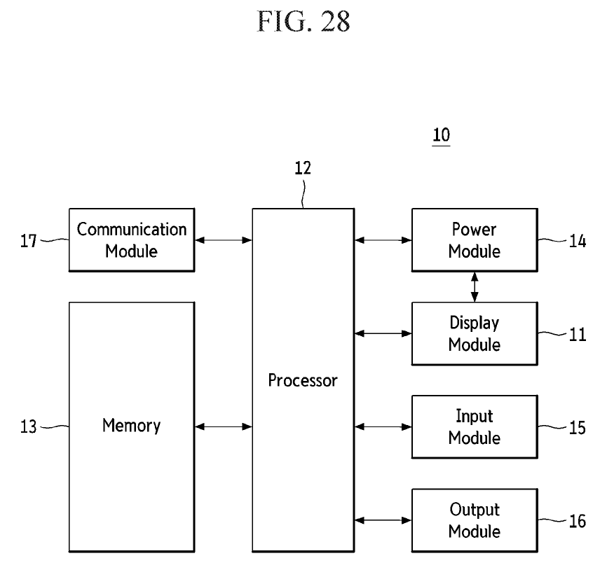

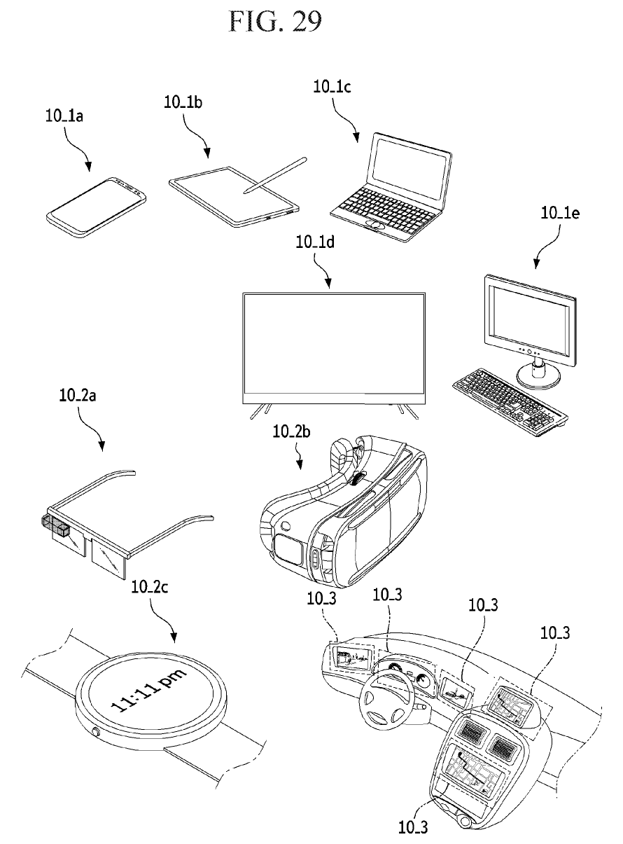

FIG. 28 is a block diagram of an electronic device according to an embodiment of the present disclosure. FIG. 29 is schematic views of electronic devices according to embodiments of the present disclosure.

Referring to FIG. 28, an electronic device 10 may include a display module 11, a processor 12, a memory 13, and a power module 14. The display module 11 may be the substantially the same as the display module 100 described above with reference to FIG. 1. In some cases, the electronic device 10 further includes an input module 15, and output module 16, and a communication module 17.

The processor 12 may include at least one of a central processing unit (CPU), an application processor (AP), a graphic processing unit (GPU), a communication processor (CP), an image signal processor (ISP), and a controller.

The memory 13 may store data information for opearting the processor 12 or the display module 11. When the processor 12 executes an application stored in the memory 13, an image data signal and/or an input control signal may be transmitted to the display module 11, and the display module 11 may process the received signal and output image information through a display screen.

The power module 14 may include a power supply module such as a power adapter or a battery device. The power module 14 may include a power conversion module. The power conversion module may convert power from the power supply module to power for operating the electronic device 10.

At least one of the respective components of the above-described electronic device 10 may be included in the display device. In addition, some of individual modules may be included in the display device, and the remaining modules may be provided separately from the display device. For example, the display device may include the display module 11, and the processor 12, the memory 13, and the power module 14 may be provided in the form of a separate module within the electronic device.

The input module 15 may be configured to receive signals from external sensors, switches, or user interfaces and converts these signals into a form the system can process. The output module may be configured to output processed signals to display devices, or other devices to perform the one or more actions. The communication module may exchange data between the device and external systems or networks, ensuring seamless connectivity and control.

Referring to FIG. 29, various electronic devices to which the display devices, according to embodiments of the present disclosure, are applied may include image display electronic devices such as a smartphone 10_1a, a tablet computer 10_1b, a laptop computer 10_1c, a television (TV) 10_1d, and a monitor 10_1e for a desktop computer. Furthermore, the electronic devices are applied may include wearable electronic devices including display modules, such as a smart glasses 10_2a, a head mounted display 10_2b, and a smart watch 10_2c. The electronic device may be implemented as vehicle electronic devices 10_3 including display modules, such as a center information display (CID) disposed on an instrument board, a center fascia, or a dashboard of a vehicle and a room mirror display.

Although embodiments of the disclosure have been described above with reference to the accompanying drawings, it will be understood by those having ordinary skill in the technical field to which the disclosure belongs that the disclosure may be practiced in other specific forms without altering the technical idea or essential features of the disclosure. It should therefore be understood that the embodiments described above are exemplary in all respects and are not necessarily intended to be limiting.

What is claimed is:

1. A display device, comprising:
a display panel including a plurality of pixels;
a lens assembly disposed on the display panel;
a first base substrate disposed between the display panel and the lens assembly; and
a plurality of lens alignment marks disposed on the first base substrate.

2. The display device of claim 1, wherein:
the display panel includes a display area and a non-display area surrounding the display area, and
wherein the plurality of lens alignment marks include:
a first lens alignment mark disposed in a display overlap area overlapping the display area; and
a second lens alignment mark disposed in a non-display overlap area overlapping the non-display area.

3. The display device of claim 2, wherein:
a width of the first lens alignment mark is different from a width of the second lens alignment mark.

4. The display device of claim 3, wherein:
the width of the first lens alignment mark is smaller than the width of the second lens alignment mark.

5. The display device of claim 1, wherein:
the lens assembly includes a plurality of lenses spaced apart from each other by a first interval, and
the plurality of lens alignment marks are spaced apart from each other by the first interval.

6. The display device of claim 1, wherein:
the lens assembly includes a lens boundary portion and a plurality of lenses disposed within the lens boundary portion, and
each of the plurality of lens alignment marks overlaps the lens boundary portion.

7. The display device of claim 1, wherein:
the display panel includes a display area and a non-display area surrounding the display area, and
a display overlap area overlapping the display area,
a vertex formed by a first side and a second side crossing the first side of the display panel, and
the plurality of lens alignment marks include a first lens alignment mark overlapping the vertex.

8. The display device of claim 7, wherein:
the plurality of lens alignment marks includes a second lens alignment mark overlapping the vertex.

9. The display device of claim 8, wherein:
the first lens alignment mark is disposed in the display overlap area, and
the second lens alignment mark is disposed in a non-display overlap area overlapping the non-display area.

10. The display device of claim 9, wherein:
a width of the first lens alignment mark is smaller than a width of the second lens alignment mark.

11. A display device, comprising:
a display panel including a plurality of pixels;
a lens assembly disposed on the display panel at a tilt angle with respect to the display panel;
a first base substrate disposed between the display panel and the lens assembly;
a second base substrate disposed on and spaced apart from the first base substrate; and
a plurality of lens alignment marks disposed on the first base substrate and aligned with the tilt angle,
wherein the plurality of lens alignment marks include:
a plurality of lower plate lens alignment marks disposed on the first base substrate; and
a plurality of upper plate lens alignment marks disposed on the second base substrate.

12. The display device of claim 11, wherein:
the display panel includes a display area and a non-display area surrounding the display area, and
each of the plurality of lower plate lens alignment marks and the plurality of upper plate lens alignment marks includes:
a first lens alignment mark disposed in a display overlap area overlapping the display area; and
a second lens alignment mark disposed in a non-display overlap area overlapping the non-display area.

13. The display device of claim 11, wherein:
the lens assembly includes a plurality of lenses spaced apart from each other by a first interval, and
the plurality of lower plate lens alignment marks are spaced apart by the first interval, and
the plurality of upper plate lens alignment marks are spaced apart from each other by the first interval.

14. The display device of claim 11, wherein:
each of the plurality of lower plate lens alignment marks overlaps the plurality of upper plate lens alignment marks.

15. The display device of claim 14, wherein:
the lens assembly includes a lens boundary portion and a plurality of lenses disposed within the lens boundary portion, and
the lower plate lens alignment mark and the upper plate lens alignment mark overlap the lens boundary portion.

16. An electronic device, comprising:
a processor configured to provide an image signal;
a display module configured to receive the image signal from the processor and to display an image; and
a power module configured to supply power to the display module,
wherein the display module includes:
a display panel including a plurality of pixels;
a lens assembly disposed on the display panel at a tilt angle with respect to the display panel;
a first base substrate disposed between the display panel and the lens assembly; and
a plurality of lens alignment marks disposed on the first base substrate and aligned with the tilt angle.

17. The electronic device of claim 16, wherein:
the display panel includes a display area and a non-display area surrounding the display area, and
wherein the plurality of lens alignment marks include:
a first lens alignment mark disposed in a display overlap area overlapping the display area; and
a second lens alignment mark disposed in a non-display overlap area overlapping the non-display area.

18. The electronic device of claim 16, wherein:
the lens assembly includes a plurality of lenses spaced apart from each other by a first interval, and
the plurality of lens alignment marks are spaced apart from each other by the first interval.

19. The electronic device of claim 16, wherein:
the lens assembly includes a lens boundary portion and a plurality of lenses disposed within the lens boundary portion, and
each of the plurality of lens alignment marks overlap the lens boundary portion.

20. The electronic device of claim 16, wherein:
the display panel includes a display area and a non-display area surrounding the display area,
a display overlap area overlapping the display area,
a vertex formed by a first side and a second side crossing the first side of the display panel, and
the plurality of lens alignment marks include a first lens alignment mark overlapping the vertex.
